(19) United States
(12) Patent Application Publication
(10) Pub. No.: US 2014/0252964 A1
(43) Pub. Date: Sep. 11, 2014

(54) DISPLAY DEVICE AND COMMON VOLTAGE GENERATOR THEREOF

(71) Applicant: AU OPTRONICS CORP., Hsin-Chu (TW)

(72) Inventors: Ming-Hung WU, Hsin-Chu (TW); Cheng-Chiu PAI, Hsin-Chu (TW)

(73) Assignee: AU OPTRONICS CORP., Hsin-Chu (TW)

(21) Appl. No.: 14/140,885

(22) Filed: Dec. 26, 2013

(30) Foreign Application Priority Data
Mar. 5, 2013 (TW) 102107688

(51) Int. Cl. G09G 3/22; H03K 19/0175

(52) U.S. Cl. CPC G09G 3/22; H03K 19/0175
USPC 315/161; 327/333

(57) ABSTRACT

A voltage generator includes a latch and a first voltage adjustment circuit. The latch includes a latch input terminal, a trigger terminal, a positive latch output terminal and a negative latch output terminal. The latch is configured to have the latch input terminal thereof for receiving an input signal, the trigger terminal thereof for receiving a trigger signal, the positive latch output terminal thereof for outputting a first latch output signal having a phase same as that of the input signal, and the negative latch output terminal thereof for outputting a second latch output signal having a phase opposite to that of the input signal. The first voltage adjustment circuit is electrically coupled to the latch and configured to output a first common voltage signal. A display device using the aforementioned voltage generator is also provided.

### TECHNICAL FIELD

The present disclosure relates to a circuit structure of a display device, and more particularly to a circuit structure of a common voltage generator of a display device.

### BACKGROUND

FIG. 1 is a schematic view of a pixel circuit adapted to a capacitive coupling driving scheme. As shown, the pixel 100 includes a transistor 102, a storage capacitor 104 and liquid crystal capacitor 106. Specifically, the transistor 102 is configured to have a first terminal thereof electrically coupled to a data line 112 and a gate terminal thereof electrically coupled to a scan line 114. The storage capacitor 104 is configured to have a first terminal thereof electrically coupled to a second terminal of the transistor 102 and a second terminal thereof electrically coupled to a common voltage Cst_com. The liquid crystal capacitor 106 is configured to have a first terminal thereof electrically coupled to the second terminal of the transistor 102 and a second terminal thereof electrically coupled to a liquid crystal common voltage Clc_com. The liquid crystal common voltage Clc_com herein is a constant DC voltage signal.

The transistor 102 is turned on while being supplied with a scan signal from the scan line 114 and meanwhile a data signal on the data line 112 is transmitted from the first terminal of the turned-on transistor 102 to the second terminal thereof for charging the storage capacitor 104; specifically, it is to be noted that the common voltage Cst_com varies the voltage level with the respective pixel row. After the charging of the storage capacitor 104 is completed, the common voltage Cst_com of the storage capacitor 104 is either pulled up or pulled down base on the configuration of the respective pixel low, thereby modulating the voltages at the second terminal of transistor 102 and liquid crystal capacitor 106 to a determined value.

However, because the existing common voltage generator has a relatively huge architecture which may require a relatively larger border, the display device cannot effectively reduce the border area to reach a narrow border requirement.

### SUMMARY

The present disclosure provides a voltage generator, which includes a latch and a first voltage adjustment circuit. The latch includes a latch input terminal, a trigger terminal, a positive latch output terminal and a negative latch output terminal. The latch is configured to have the latch input terminal thereof for receiving an input signal, the trigger terminal thereof for receiving a trigger signal, the positive latch output terminal thereof for outputting a first latch output signal having a phase same as that of the input signal, and the negative latch output terminal thereof for outputting a second latch output signal having a phase opposite to that of the input signal. The first voltage adjustment circuit is electrically coupled to the latch and configured to output a first common voltage signal.

The present disclosure further provides a display device, which includes a display area and a plurality of common voltage generators. The display area includes a plurality of pixel rows, a plurality of scan lines and a plurality of common voltage lines. Each one of the scan lines and each one of the common voltage lines is corresponding to one of the pixel rows. Each one of the pixel rows is constituted by a plurality of pixel units. The common voltage generators are electrically coupled to the common voltage lines, respectively. Each one of the common voltage generators is corresponding to at least one of the pixel rows and includes a latch and a voltage adjustment circuit. The latch includes a latch input terminal, a trigger terminal, a positive latch output terminal and a negative latch output terminal. The latch is configured to have the latch input terminal thereof for receiving an input signal, the trigger terminal thereof for receiving a trigger signal, the positive latch output terminal thereof for outputting a first latch output signal having a phase same as that of the input signal, and the negative latch output terminal thereof for outputting a second latch output signal having a phase opposite to that of the input signal. The voltage adjustment circuit is electrically coupled to the latch and configured to output a first common voltage signal to a corresponding common voltage line.

The present disclosure still further provides a display device, which includes a display, a plurality of first common voltage generators and a plurality of second common voltage generators. The display area includes a plurality of pixel rows, a plurality of scan lines and a plurality of common voltage lines. Each one of the scan lines and each one of the common voltage lines is corresponding to one of the pixel rows. The first common voltage generators are disposed on a first side of the display area and each are configured to provide a common voltage signal to the respective two adjacent pixel rows. The second common voltage generators are disposed on a second side of the display area and each are configured to provide the common voltage signal to the respective two adjacent pixel rows. Each one of the first and second common voltage generators includes a latch, a buffer circuit, a multiplexer, a first voltage adjustment circuit and a second voltage adjustment circuit. The latch includes a latch input terminal for receiving an input signal, a trigger terminal for receiving a scan signal, a positive latch output terminal for outputting a positive latch output signal having a phase same as that of the input signal, and a negative latch output terminal for outputting a negative latch output signal having a phase opposite to that of the input signal. The buffer circuit includes an input terminal electrically coupled to the positive latch output terminal of the latch. The first voltage adjustment circuit is configured to output a common voltage signal corresponding to a first of two adjacent pixel rows according to the potential level at an output terminal of the buffer circuit. The multiplexer includes a first multiplex input terminal, a second multiplex input terminal, a selection terminal and a multiplex output terminal. The first and second multiplex input terminals are electrically coupled to the positive and negative latch output terminals of the latch, respectively. The selection terminal is electrically coupled to the scan signal received by the latch. The multiplexer is configured to output either the first latch output signal or the second latch output signal via the multiplex output terminal thereof according to the scan signal. The second voltage adjustment circuit is electrically coupled to the multiplexer and configured to output a common voltage signal corresponding to a second of the two adjacent rows of pixel according to the potential level at the multiplex output terminal.

### BRIEF DESCRIPTION OF THE DRAWINGS

The present disclosure will become more readily apparent to those ordinarily skilled in the art after reviewing the following detailed description and accompanying drawings, in which:

FIG. 1 is a schematic view of a conventional pixel driving circuit of a display device;

FIGS. 2A, 2B each are schematic circuit structure views of a common voltage generator in accordance with an embodiment of the present disclosure;

FIG. 3A is a schematic structure view of a display device in accordance with the first embodiment of the present disclosure;

FIG. 3B is a schematic timing sequence view of the signals associated with the display device in the first embodiment of the present disclosure;

FIG. 4A is a schematic structure view of a display device in accordance with the second embodiment of the present disclosure;

FIG. 4B is a schematic timing sequence view of the signals associated with the display device in the second embodiment of the present disclosure;

FIG. 5A is a schematic structure view of a display device in accordance with the third embodiment of the present disclosure;

FIG. 5B is a schematic timing sequence view of the signals associated with the display device in the third embodiment of the present disclosure;

FIG. 6 is a schematic structure view of a pixel driving circuit associated with the third embodiment of the present disclosure;

FIG. 7 is a schematic structure view of a display device in accordance with the fourth embodiment of the present disclosure;

FIG. 8A is a schematic structure view of a display device in accordance with the fifth embodiment of the present disclosure;

FIG. 8B is a schematic timing sequence view of the signals associated with the display device in the fifth embodiment of the present disclosure;

FIG. 9 is a schematic structure view of a display device in accordance with the sixth embodiment of the present disclosure;

FIGS. 10A, 10B each are schematic circuit structure views of a common voltage generator in accordance with another embodiment of the present disclosure;

FIG. 11A is a schematic structure view of a display device in accordance with the seventh embodiment of the present disclosure;

FIG. 11B is a schematic timing sequence view of the signals associated with the display device in the seventh embodiment of the present disclosure;

FIG. 12A is a schematic structure view of a display device in accordance with the eighth embodiment of the present disclosure;

FIGS. 12B, 12C each are schematic circuit structure views of a latch circuit in FIG. 12A in accordance with another embodiment of the present disclosure;

FIG. 12D is a schematic timing sequence view of the signals associated with the display device in the eighth embodiment of the present disclosure; and

FIG. 13 is a schematic structure view of a display device in accordance with the ninth embodiment of the present disclosure.

### DETAILED DESCRIPTION OF PREFERRED EMBODIMENTS

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

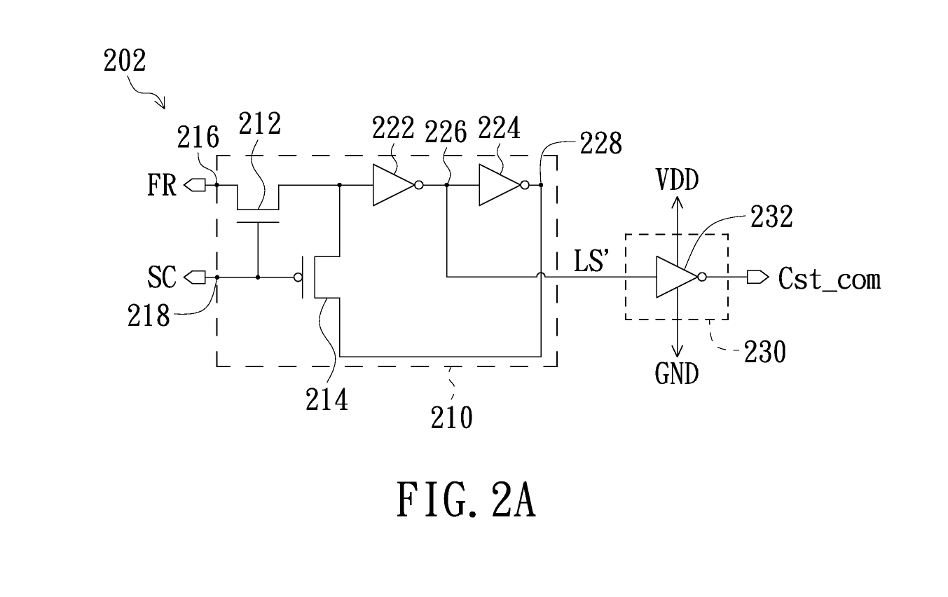

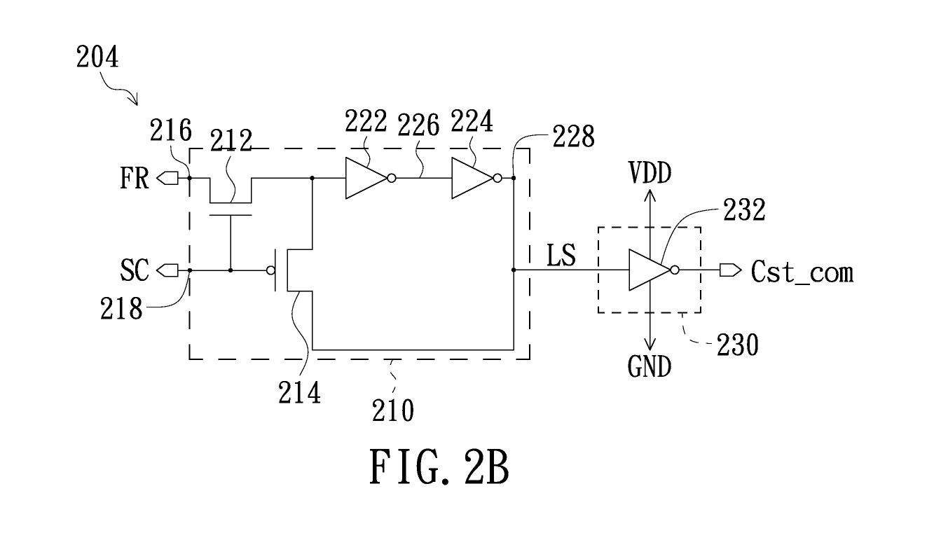

FIGS. 2A and 2B are schematic structure views of a common voltage generator in accordance with an embodiment of the present disclosure. Please refer to FIG. 2A first, the common voltage generator 202 in this embodiment includes a latch 210 and a voltage adjustment circuit 230. The latch 210 has a latch input terminal 216, a trigger terminal 218, a negative latch output terminal 226 and a positive latch output terminal 228. The latch 210 is configured to have the latch input terminal 216 thereof for receiving an input signal FR provided from external (e.g., a timing controller), and the trigger terminal 218 thereof for receiving a scan signal SC as a trigger signal.

The latch 210 includes switch units 212, 214. In one embodiment, the switch unit 212 is configured to have a first terminal thereof electrically coupled to the latch input terminal 216 and a control terminal thereof electrically coupled to the trigger terminal 218. The switch unit 214 is configured to have a first terminal and a control terminal thereof electrically coupled to a second terminal and the control terminal of the switch unit 212, respectively. In this embodiment, the switch unit 212 is configured to have the first and second terminals thereof electrically conductive to each other while the trigger signal (i.e., the scan signal SC) has a first potential level; and the switch unit 214 is configured to have the first and second terminals thereof electrically conductive to each other while the trigger signal (i.e., the scan signal SC) has a second potential level. Specifically, the first potential level herein is referred to as a positive potential level (or, a logic high potential level); and the second potential level herein is referred to as a negative potential level (or, a logic low potential level).

In this embodiment, the switch units 212, 214 each may be realized by a transistor; wherein the transistors 212, 214 have opposite electrical characteristics. In this embodiment, the switch unit 212 may be implemented by an N-type thin film transistor, and the switch unit 214 may be implemented by a P-type thin film transistor; however, the present invention is not limited thereto.

As shown in FIG. 2A, the latch 210 further includes inverters 222, 224. The inverter 222 is configured to have an input terminal thereof electrically coupled to the second terminal of the switch unit 212 and an output terminal thereof electrically coupled to the negative latch output terminal 226 of the latch 210. The inverter 224 is configured to have an input terminal thereof electrically coupled to the output terminal of the inverter 222 and an output terminal thereof electrically coupled to the second terminal of the switch unit 214 and the positive latch output terminal 228 of the latch 210. In this embodiment, the voltage adjustment circuit 230 is electrically coupled to the negative latch output terminal 226 of the latch 210 and configured to generate a storage capacitor common voltage signal Cst_com according to the potential level at the negative latch output terminal 226.

As shown in FIG. 2B, the common voltage generator 204 in this embodiment has a circuit structure similar to that of the common voltage generator 202 in FIG. 2A. The main difference between the two is that the voltage adjustment circuit 230 in the common voltage generator 204 is electrically coupled to the positive latch output terminal 228 and configured to generate the storage capacitor common voltage signal Cst_com according to the potential level at the positive latch output terminal 228. In one embodiment, the voltage adjustment circuit 230 may be implemented by an inverter 232, which is configured to have an input terminal thereof selectively electrically coupled to the negative latch output terminal 226 or the positive latch output terminal 228, a first terminal thereof electrically coupled to the source voltage VDD, a second terminal thereof electrically coupled to ground GND, and an output terminal thereof for outputting the storage capacitor common voltage signal Cst_com. The operations of the common voltage generators 202, 204 will be described in detail in follow.

### First Embodiment

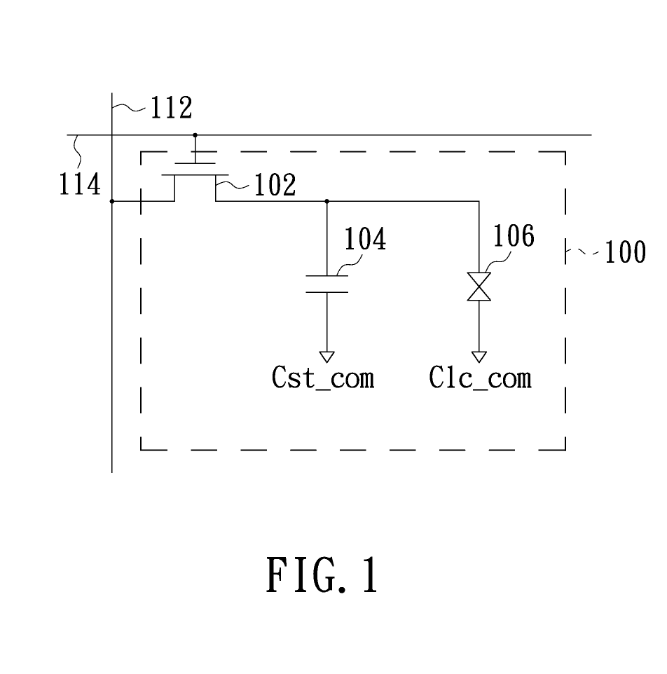

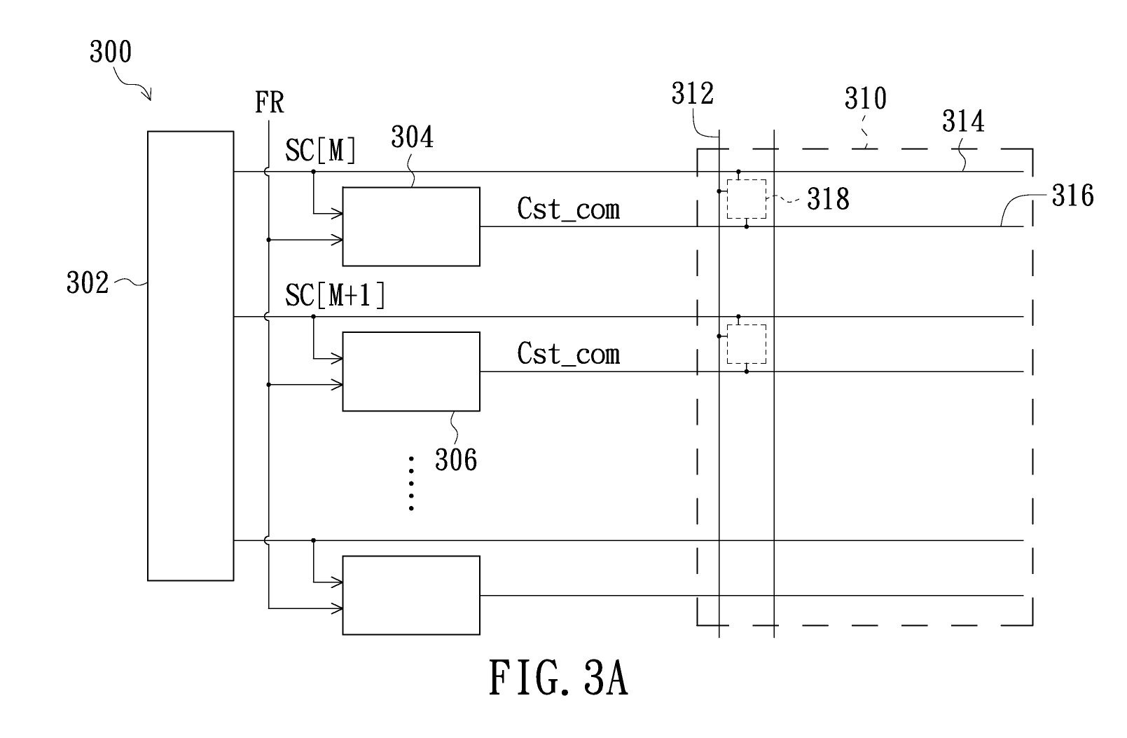

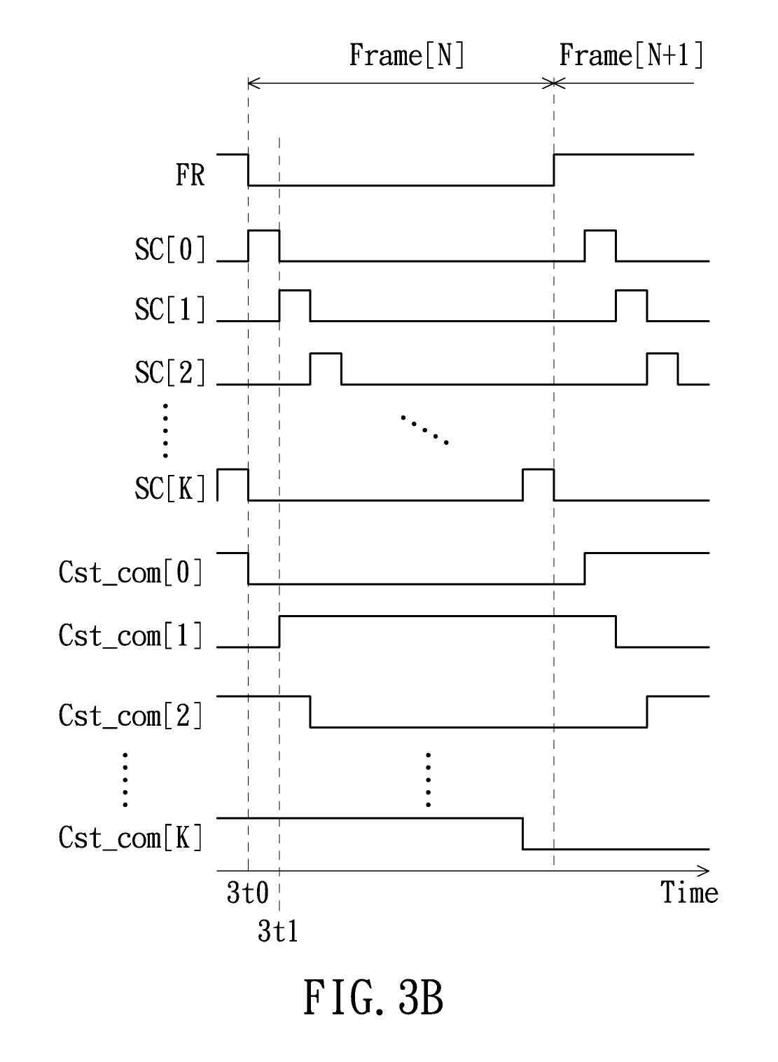

FIG. 3A is a schematic structure view of a display device in accordance with the first embodiment of the present disclosure. As shown, the display device 300 in this embodiment includes a gate driving module 302, a plurality of first common voltage generators 304, a plurality of second common voltage generators 306 and a display area 310. The display area 310 is disposed with a plurality of scan lines 314 and a plurality of common voltage lines 316; wherein each of the scan lines 314 and common voltage lines 316 is corresponding to one respective row of pixel. The first common voltage generator 304 and the second common voltage generator 306 are arranged in a staggered manner. Specifically, the first common voltage generators 304 are electrically coupled to the respective odd-numbered rows of pixel; and the second common voltage generator 306 are electrically coupled to the respective even-numbered rows of pixel. In addition, the display area 310 is further disposed with a plurality of data lines 312; wherein the extending direction of the data line 312 is substantially perpendicular to that of the scan line 314. Furthermore, a pixel 318 is arranged within an area defined by a respective data line 312, a respective scan line 314 and a respective common voltage line 316. The pixel 318 in this embodiment may have a circuit structure disclosed in FIG. 1; but the present invention is not limited thereto.

The gate driving module 302 is configured to output a plurality of scan signals SC; wherein each one of the scan signals SC is corresponding to one respective scan line 314. In addition, as mentioned above, each one of the first common voltage generators 304 and the second common voltage generators 306 is electrically coupled to either odd-numbered or even-numbered row of pixel 318. Specifically, because one input terminal of the common voltage generator (304 or 306) corresponding to the Mₜₕ pixel row is electrically coupled to the scan line 314 corresponding to the Mₜₕ pixel row, the common voltage generator (304 or 306) corresponding to the Mₜₕ pixel row is configured to generate the storage capacitor common voltage signal Cst_com according to the scan signal SC[M] and the input signal FR and output the generated storage capacitor common voltage signal Cst_com to the scan line 314 corresponding to the Mₜₕ row of pixel 318; wherein M is a natural number. In this embodiment, the first common voltage generators 304 are electrically coupled to the respective odd-numbered rows of pixel 318 and accordingly the second common voltage generators 306 are electrically coupled to the respective even-numbered rows of pixel 318; however, the first common voltage generators 304 may be electrically coupled to the respective even-numbered pixel rows and accordingly the second common voltage generators 306 may be electrically coupled to the respective odd-numbered pixel rows in another embodiment. In addition, it is to be noted that the first common voltage generator 304 and the second common voltage generator 306 may be implemented by the common voltage generators 202, 204 shown in FIGS. 2A, 2B, respectively.

FIG. 3B is a schematic timing sequence view of the signals associated with the display device 300 in the first embodiment of the present disclosure. Please refer to FIGS. 2A, 2B, 3A and 3B. In this embodiment, the first common voltage generators 304 are implemented by the common voltage generator 202 and are disposed corresponding to the respective even-numbered pixel rows (i.e., the rows 0, 2, 4 . . . ); and the second common voltage generators 306 are implemented by the common voltage generator 204 and are disposed corresponding to the respective the odd-numbered pixel rows (i.e., the rows 1, 3, 5 . . . ). In this embodiment, the display panel 300 is configured to start a new frame when the scan signal SC[0] corresponding to the zero row is being enable.

For example, at time 3t0, the display panel 300 is indicated, by the being-enable scan signal SC[0], as being ready to start a new frame and the input signal FR is converted from a first potential level to a second potential level. Specifically, the input signal FR is converted from a high potential level to a low potential level at time 3t0 in this embodiment. Meanwhile at time 3t0, the switch unit 214 in the first common voltage generator 304 (hereafter is also referred to the common voltage generator 202) corresponding to the zero row is turned off and the switch unit 212 therein is turned on. Thus, a low-potential-level input signal FR is delivered to the input terminal of the inverter 222 via the turned-on switch unit 212 and accordingly a low-potential-level latch output signal LS is outputted from the positive latch output terminal 228 and a high-potential-level latch output signal LS′ is outputted from the negative latch output terminal 226. Consequentially, the voltage adjustment circuit 230 generates and outputs a storage capacitor common voltage signal Cst_com[0] having a potential level of ground GND in response to a receiving of the latch output signal LS′ at time 3t0.

Then, at time 3t1, the scan signal SC[0] is disable and accordingly the switch unit 212 in the common voltage generator 202 is turned off and the switch unit 214 therein is turned on. Thus, the potential level at the input terminal of the inverter 222 is equal to that of the signal at the output terminal of the inverter 224 and the latch output terminals 226, 228 each are maintained to have a fixed potential level until the scan signal SC[0] is enable again.

Meanwhile at time 3t1, the scan signal SC[1] is enable and accordingly the switch unit 214 in the first common voltage generator 306 (hereafter is also referred to the common voltage generator 204) corresponding to the first row is turned off and the switch unit 212 therein is turned on. Thus, a low-potential-level input signal FR is delivered to the input terminal of the inverter 222 via the turned-on switch unit 212 and accordingly a low-potential-level latch output signal LS is outputted from the positive latch output terminal 228. Consequentially, the voltage adjustment circuit 230 generates and outputs a storage capacitor common voltage signal Cst_com[1] having a potential level of source voltage VDD in response to a receiving of the latch output signal LS at time 3t1. Based on the same manner, the operations of the remaining first common voltage generators 304 corresponding to the respective even-numbered pixel rows (i.e., the rows 2, 4, 6 . . . ) and second common voltage generators 306 corresponding to the respective even-numbered pixel rows (i.e., the rows 3, 5, 7 . . . ) are obtained, and no redundant detail is to be given herein.

In a preferred embodiment, the first and second potential levels are configured to have a 5V difference therebetween; and the voltage source VDD and the ground GND are configured to have a 5V difference therebetween.

In this embodiment, the first common voltage generator 304 is exemplarily implemented by the common voltage generator 202 and the second common voltage generator 306 is exemplarily implemented by the common voltage generator 204. However, it is understood that the first common voltage generator 304 may be implemented by the common voltage generator 204 and the second common voltage generator 306 may be implemented by the common voltage generator 202 in another embodiment; and the present invention is not limited thereto and no redundant detail is to be given hereafter.

### Second Embodiment

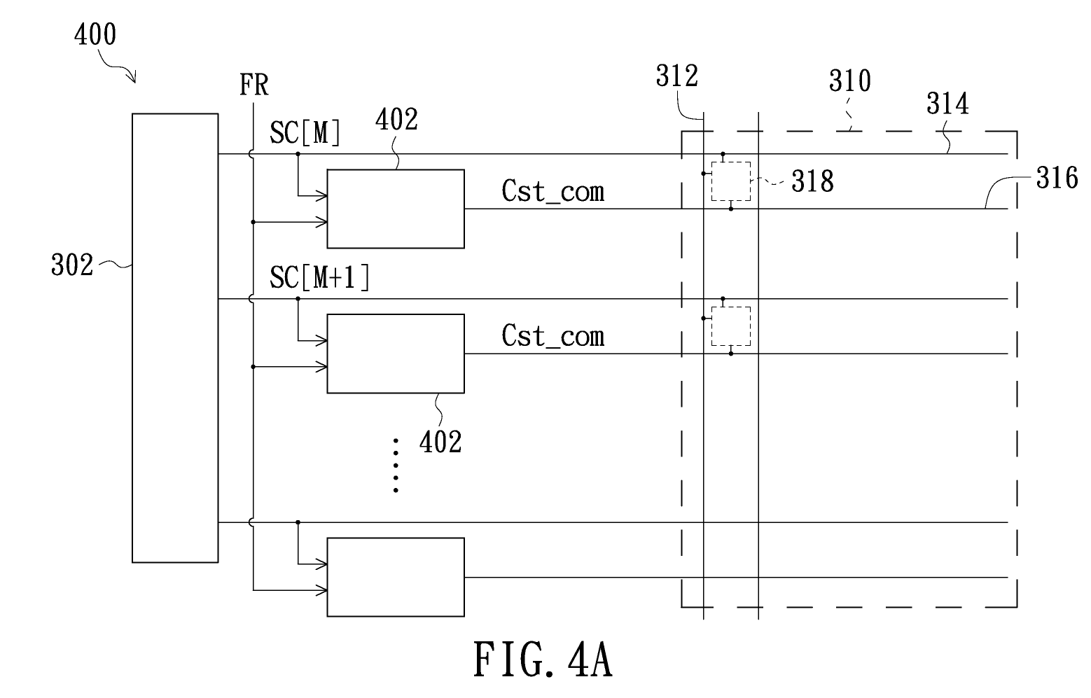

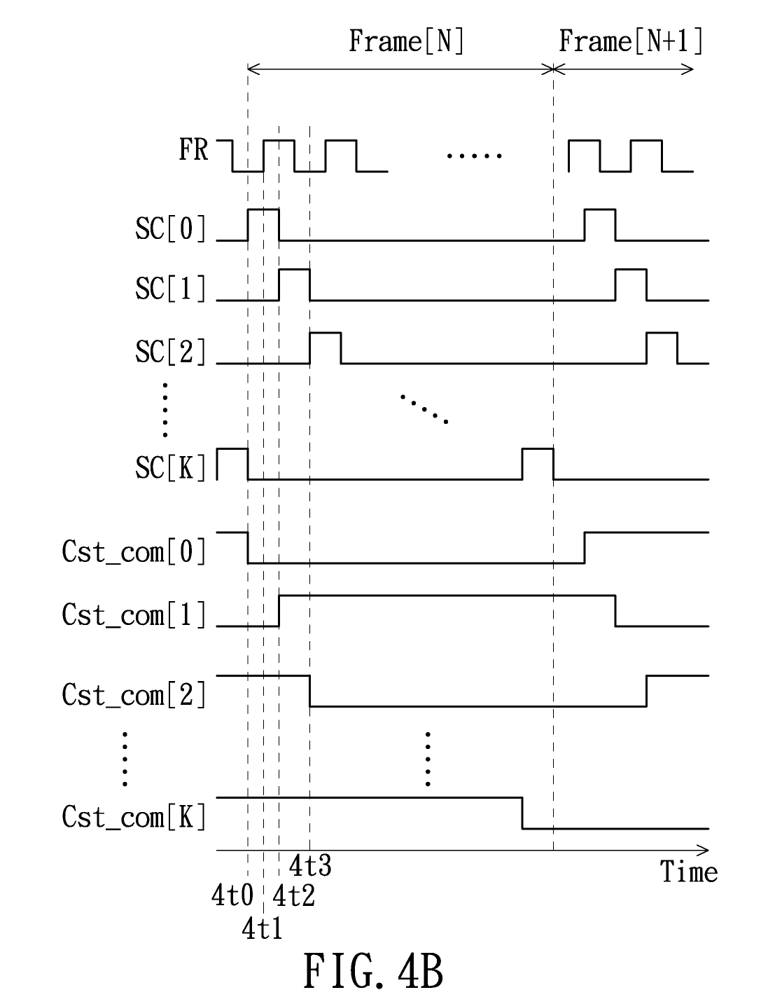

FIG. 4A is a schematic structure view of a display device in accordance with the second embodiment of the present disclosure. As shown, the display device 400 in this embodiment has a circuit structure similar to that of the display device 300. The main difference between the two is that all the common voltage generators 402, for generating the storage capacitor common voltage signal Cst_com, in the display device 400 have the same circuit structure. The common voltage generator 402 herein may be implemented by either the common voltage generator 202 or the common voltage generator 204; specifically, the common voltage generator 402 in this embodiment is exemplarily implemented by the common voltage generator 202, and the present invention is not limited thereto.

FIG. 4B is a schematic timing sequence view of the signals associated with the display device 400 in the second embodiment of the present disclosure. Please refer to FIGS. 2A, 4A and 4B. In this embodiment, the input signal FR is configured to oscillate between the first and second potential levels within one frame and thereby a plurality of pulses are formed therein. Thus, by configuring the input signal FR in this specific manner, the two adjacent scan signals SC[M] and SC[M+1] have opposite potential levels within the corresponding pulse in the input signal FR.

In this embodiment, specifically, if a high-potential-level storage capacitor common voltage signal Cst_com is desired to be outputted, the enable time of the corresponding scan signal SC is required to shift a predetermined phase and thereby configuring the rising edge of each pulse of the input signal FR and that of the corresponding scan signal SC to have a predetermined phase therebetween. Alternatively, if a low-potential-level storage capacitor common voltage signal Cst_com is desired to be outputted, the enable time of the corresponding scan signal SC is required to shift a predetermined phase and thereby configuring the falling edge of each pulse of the input signal FR and the rising edge of the corresponding scan signal SC to have a predetermined phase therebetween.

For example, at time 4t0, the scan signal SC[0] is being enable (having a rising edge) and the input signal FR has a second potential level (e.g., a low potential level) until at time 4t1. Thus, at time 4t0, the switch unit 214 in the first common voltage generator 402 (hereafter is also referred to the common voltage generator 202) corresponding to the zero row is turned off and the switch unit 212 therein is turned on. Then, a low-potential-level input signal FR is delivered to the input terminal of the inverter 222 via the turned-on switch unit 212 and accordingly a high-potential-level latch output signal LS′ is outputted from the negative latch output terminal 226. Consequentially, the voltage adjustment circuit 230 generates and outputs a storage capacitor common voltage signal Cst_com[0] having a potential level of ground GND in response to a receiving of the latch output signal LS′ at time 4t0.

Then, at time 4t2, the scan signal SC[1] is enable and accordingly the switch unit 214 in the common voltage generator 202 corresponding to the first row is turned off and the switch unit 212 therein is turned on. Meanwhile at time 4t2, the input signal FR is switched to a first potential level (e.g., a high potential level) and accordingly a low-potential-level latch output signal LS′ is outputted from the negative latch output terminal 226. Consequentially, the voltage adjustment circuit 230 generates and outputs a storage capacitor common voltage signal Cst_com[1] having a potential level of source voltage VDD in response to a receiving of the latch output signal LS′ at time 4t1.

Then, at time 4t3, the scan signal SC[2] is enable and the input signal FR is switched to the second potential level (e.g., a low potential level). Thus, the voltage adjustment circuit 230 in the common voltage generator 202 corresponding to the second row generates and outputs a storage capacitor common voltage signal Cst_com[2] having a potential level of ground GND. Based on the same manner, the operations of the remaining common voltage generators 402 corresponding to the respective pixel rows (i.e., the rows 3, 4, 5 . . . ) are obtained, and no redundant detail is to be given herein.

### Third Embodiment

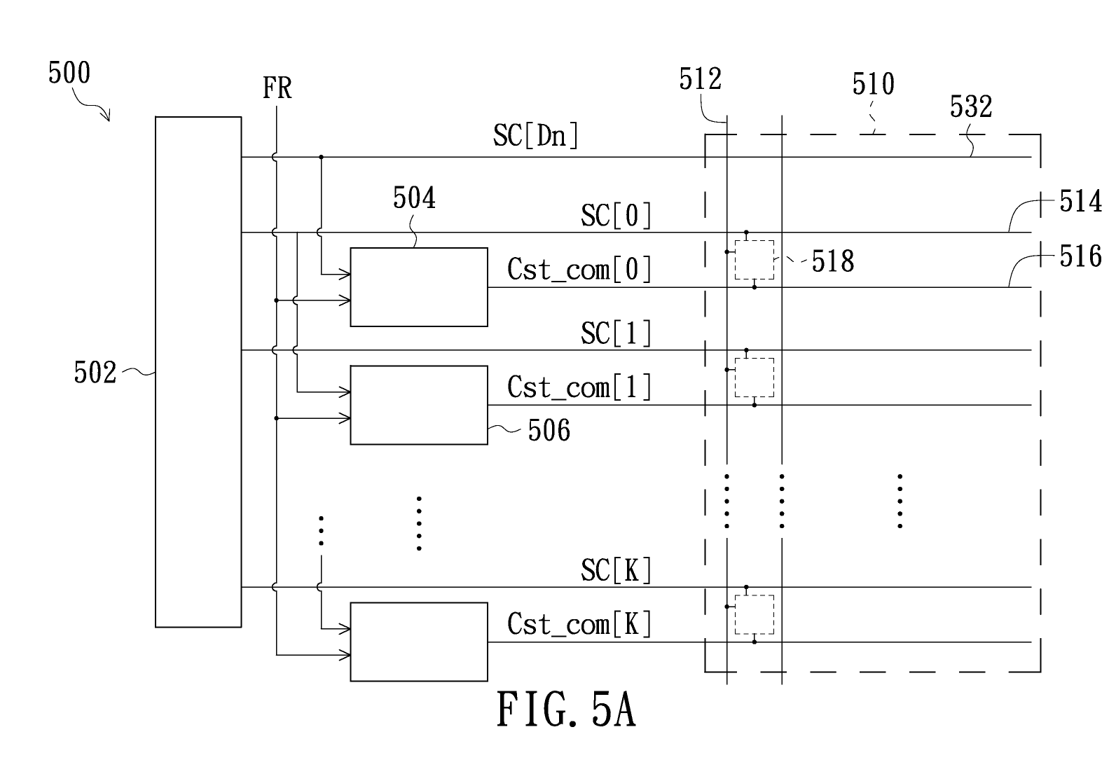

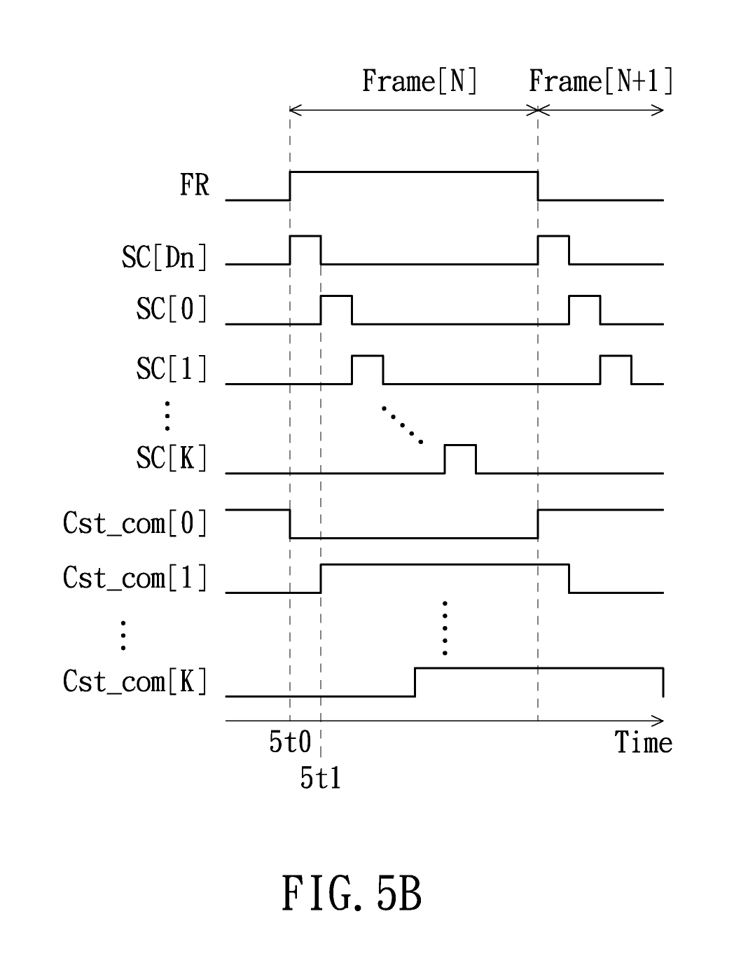

FIG. 5A is a schematic structure view of a display device in accordance with the third embodiment of the present disclosure. As shown, the display device 500 in this embodiment includes a gate driving module 502, a plurality of first common voltage generators 504, a plurality of second common voltage generators 506 and a display area 510. The display area 510 is disposed with a plurality of data lines 512, a plurality of scan lines 514 and a plurality of common voltage lines 516. Furthermore, a pixel 518 is arranged within an area defined by a respective data line 512, a respective scan line 514 and a respective common voltage line 516.

Specifically, in this embodiment, the common voltage generator (504 or 506) corresponding to the Mₜₕ pixel row is electrically coupled to the (M−n)ₜₕ scan line and configured to generate the storage capacitor common voltage signals Cst_com[M] of the Mₜₕ common voltage line 516 according to the scan signal SC[M−n] transmitted by the (M−n)ₜₕ scan line 514. To configure each common voltage generator (504 or 506) to electrically couple to the (M−n)ₜₕ scan line 514, the display device 500 further includes n dummy scan lines 532 disposed before the first scan line 514; wherein n is a positive integer such as 1 or 2, but the present disclosure is not limited thereto. It is to be noted that the gate driving module 502 is further configured to provide the dummy scan signal SC[Dn] to the dummy scan line(s) 532.

In this embodiment, the aforementioned n is 1. In addition, the first common voltage generator 504 may have a circuit structure same as that of the common voltage generator 204 in FIG. 2B and be electrically coupled to the respective even-numbered scan line 514; and the second common voltage generator 506 may have a circuit structure same as that of the common voltage generator 202 in FIG. 2A and be electrically coupled to the respective odd-numbered scan line 514. FIG. 5B is a schematic timing sequence view of the signals associated with the display device 500 in the third embodiment of the present disclosure. Please refer to FIGS. 2A, 2B, 5A and 5B. As shown, in this embodiment, the switch units 212 and 214 in the common voltage generators 504 and 606 (hereafter are also referred to the common voltage generators 204 and 202, respectively) corresponding to the Mₜₕ pixel row are configured to have the gate terminals thereof electrically coupled to the scan signal SC[M−n] and to be turned-on or turned-off according to the potential level of the scan signal SC[M−n]. Furthermore, in this embodiment, the display device 500 starts a new frame when the dummy scan signal SC[D0] on the dummy scan line 532 is being enable at time 5t0 and the input signal FR is switched from a first potential level (e.g., a low potential level) to a second potential level (e.g., a high potential level).

Meanwhile at time 5t0, the dummy scan signal SC[D0] is enable and accordingly the common voltage generator 204 generates and outputs a storage capacitor common voltage signal Cst_com[0] having a potential level of ground GND according to the operation manner as illustrated in FIG. 2B. Then, at time 5t1, the scan signal SC[0] is enable and accordingly the common voltage generator 202 generates and outputs a storage capacitor common voltage signal Cst_com[1] having a potential level of source voltage VDD according to the operation manner as illustrated in FIG. 2A.

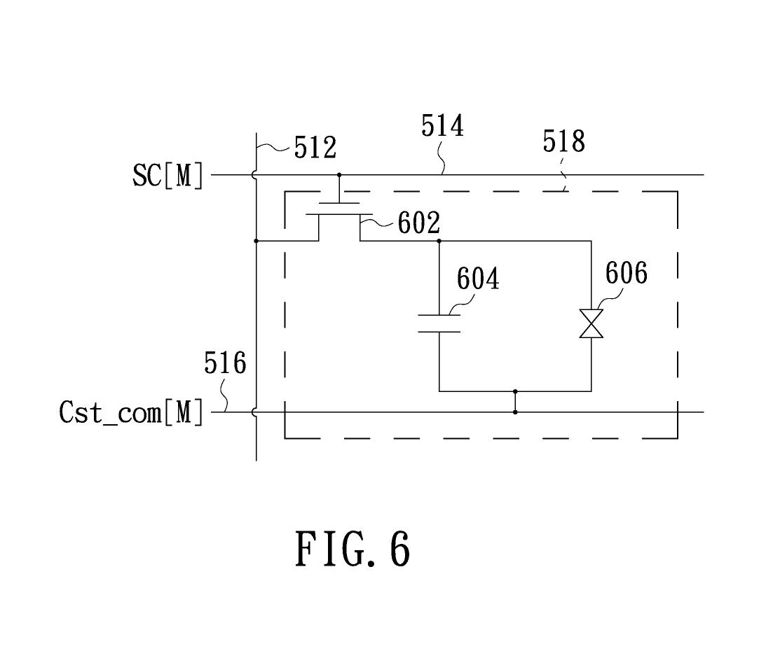

The common voltage generator disclosed in the third embodiment is adapted to be used for a display panel with a wide viewing angle feature, especially for driving in-plane switch (IPS) pixels; and the present invention is not limited thereto. FIG. 6 is a schematic structure view of a pixel driving circuit associated with the third embodiment of the present disclosure. As shown, the pixel 518 on a wide-viewing-angle display panel includes a transistor 602, a storage capacitor 604 and a liquid crystal capacitor 606. The transistor 602 is configured to have a first terminal thereof electrically coupled to a corresponding data line 512 and a gate terminal thereof electrically coupled to a corresponding scan line 514. The storage capacitor 604 and the liquid crystal capacitor 606 both are configured to have two terminals thereof respectively electrically coupled to the second terminal of the transistor 602 and a corresponding common voltage line 516.

Specifically, the transistor 602 is turned on while the scan signal SC[M] is enable; and accordingly the data signal transmitted from the data line 512 is further delivered to the storage capacitor 604 via the turned-on transistor 602 to charge the storage capacitor 604 and drive the liquid crystal capacitor 606.

### Fourth Embodiment

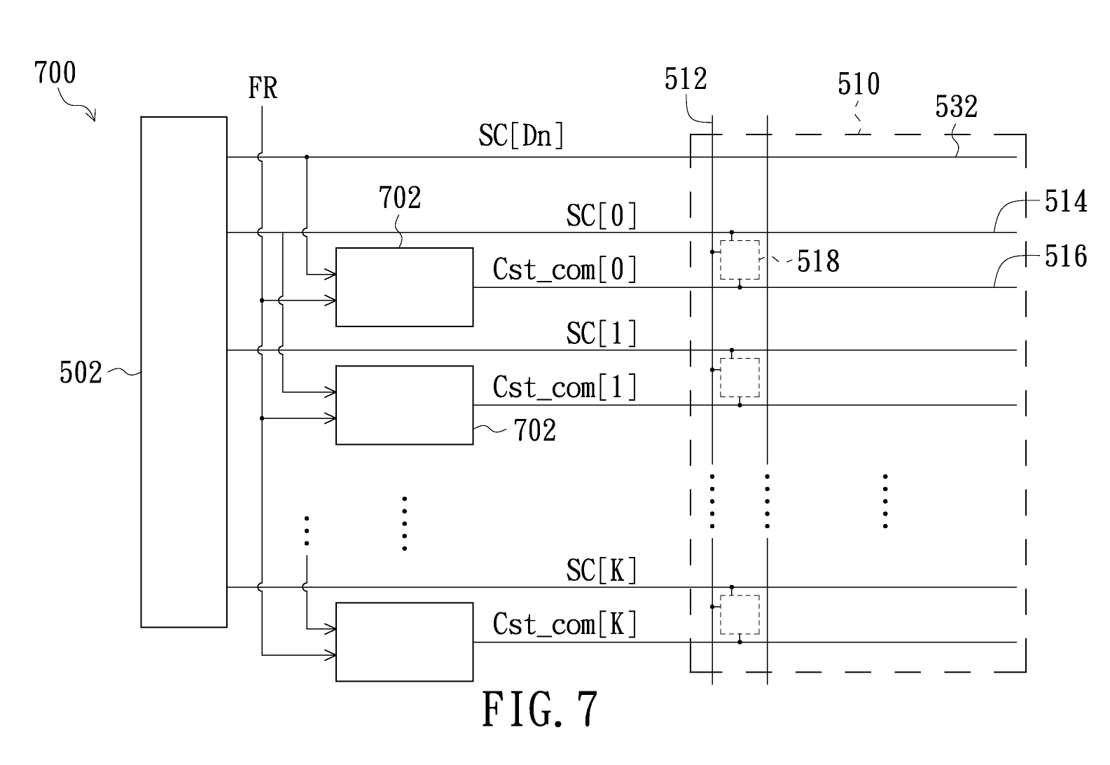

FIG. 7 is a schematic structure view of a display device in accordance with the fourth embodiment of the present disclosure. As shown, the display device 700 in this embodiment has a circuit structure similar to that of the display device 500. The main difference between the two is that all the storage capacitor common voltage signals Cst_com corresponding to both of the odd-numbered and even-numbered pixel rows are generated by the same common voltage generators 702 in the display device 700; wherein the common voltage generators 702 herein may have a circuit structure same as that of the common voltage generators 202 or 204.

In response to the above-described circuit structure, the signals associated with the display device 700 may be configured to have the timing sequences as schematically illustrated in FIG. 5, except the input signal FR is required to be modulated to oscillate within a frame cycle and have an offset with a predetermined phase as shown in FIG. 4B and thereby configure the storage capacitor common voltage signals Cst_com corresponding to adjacent pixel rows to have different polarities.

### Fifth Embodiment

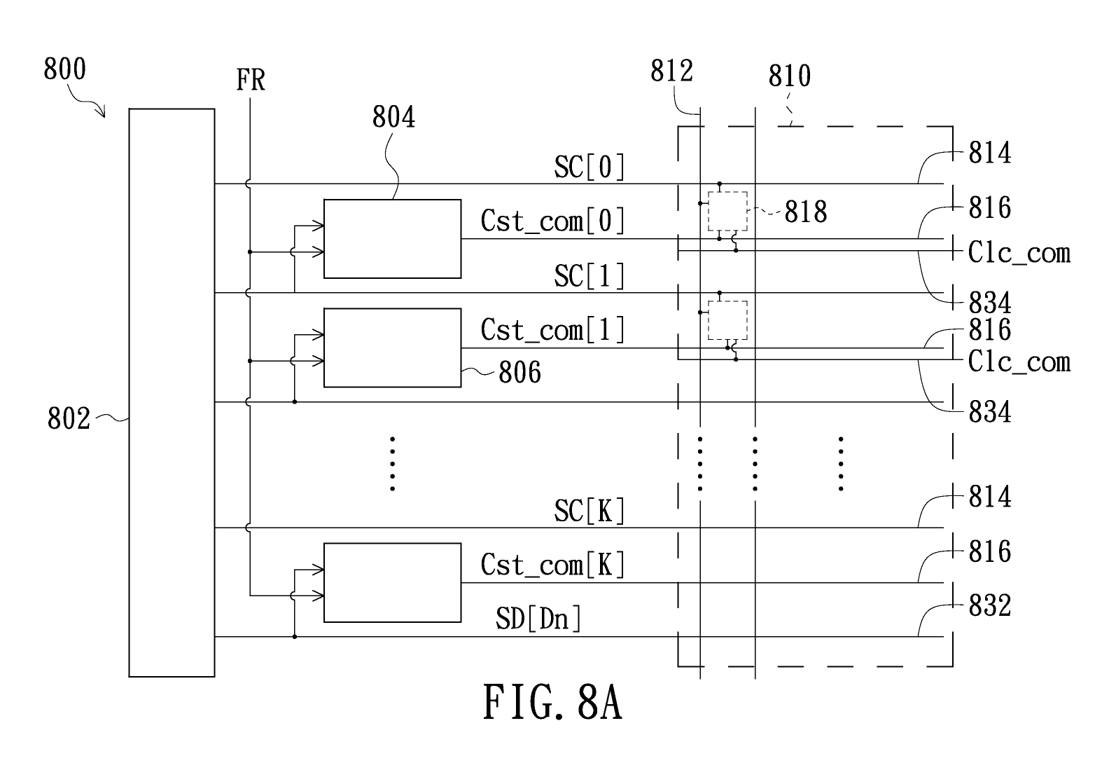

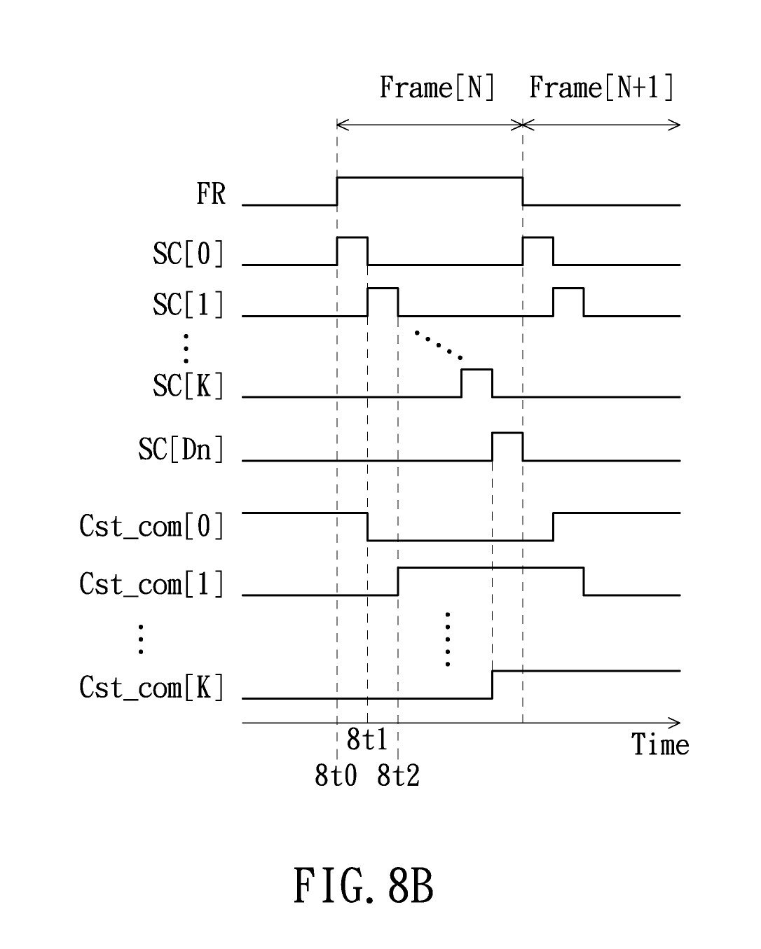

FIG. 8A is a schematic structure view of a display device in accordance with the fifth embodiment of the present disclosure. As shown, the display device 800 in this embodiment includes a gate driving module 802, a plurality of first common voltage generators 804, a plurality of second common voltage generators 806 and a display area 810. The display area 810 is disposed with a plurality of data lines 812, a plurality of scan lines 814 and a plurality of common voltage lines 816. The gate driving module 802 is configured to output scan signal SC[M] to the corresponding scan line 814.

Specifically, in this embodiment, the common voltage generator (804 or 806) corresponding to the Mₜₕ pixel row is electrically coupled to the (M+n)ₜₕ scan line 814 and configured to generate the storage capacitor common voltage signals Cst_com[M] corresponding to the Mₜₕ common voltage line 816 according to the scan signal SC[M+n] transmitted by the (M+n)ₜₕ scan line 814. To configure the common voltage generator (804 or 806) to electrically couple to the (M+n)ₜₕ scan line 814, the display device 800 is further disposed with n dummy scan lines 832 after the last scan line 814; wherein generally n is 1 or 2, but the present disclosure is not limited thereto. Correspondingly, it is to be noted that the gate driving module 802 is further configured to provide the dummy scan signal SC[Dn] to the dummy scan line(s) 832.

In addition, the display area 810 is further disposed with a plurality of common voltage lines 834 for providing constant DC liquid crystal common voltage signal Clc_com to respective pixels 818; wherein each pixel 818 may have a circuit structure same as that of the pixel 100 disclosed in FIG. 1.

In this embodiment, the aforementioned n is 1. In addition, the first common voltage generator 804 may have a circuit structure same as that of the common voltage generator 204 in FIG. 2B; and the second common voltage generator 806 may have a circuit structure same as that of the common voltage generator 202 in FIG. 2A. Specifically, in this embodiment, the switch unit 212 or 214 in the common voltage generator 804 or 806 (hereafter are also referred to the common voltage generator 204 or 202, respectively) corresponding to the Mₜₕ pixel row is configured to have the gate terminal thereof electrically coupled to the scan signal SC[M+n] corresponding to the (M+n)ₜₕ pixel row and to be turned-on or turned-off according to the scan signal SC[M+n]. FIG. 8B is a schematic timing sequence view of the related signals in the display device 800 in the fifth embodiment of the present disclosure. Please refer to FIGS. 2A, 2B, 8A and 8B. As shown, in this embodiment, the display device 800 starts a new frame when the scan signal SC[D0] is being enable at time 8t0. Because the common voltage generators 204 and 202 are configured to generate the storage capacitor common voltage signals Cst_com[M] according to the scan signal SC[M+n], the storage capacitor common voltage signals Cst_com[M] is maintained to have the prior potential level even the scan signal SC[0] is being enable at time 8t0 until the scan signal SC[0+n] is enable.

At time 8t1, the scan signal SC[1] is enable; and accordingly a low-potential-level storage capacitor common voltage signals Cst_com[1] is generated by the common voltage generator 204 corresponding to the zero pixel row. Based on the same manner, at time 8t2, the scan signal SC[2] is enable; and accordingly a high-potential-level storage capacitor common voltage signals Cst_com[1] is generated by the common voltage generator 202 corresponding to the first pixel row. The generation of the storage capacitor common voltage signals Cst_com[M] can be obtained based on the aforementioned manner, and no redundant detail is to be given herein.

### Sixth Embodiment

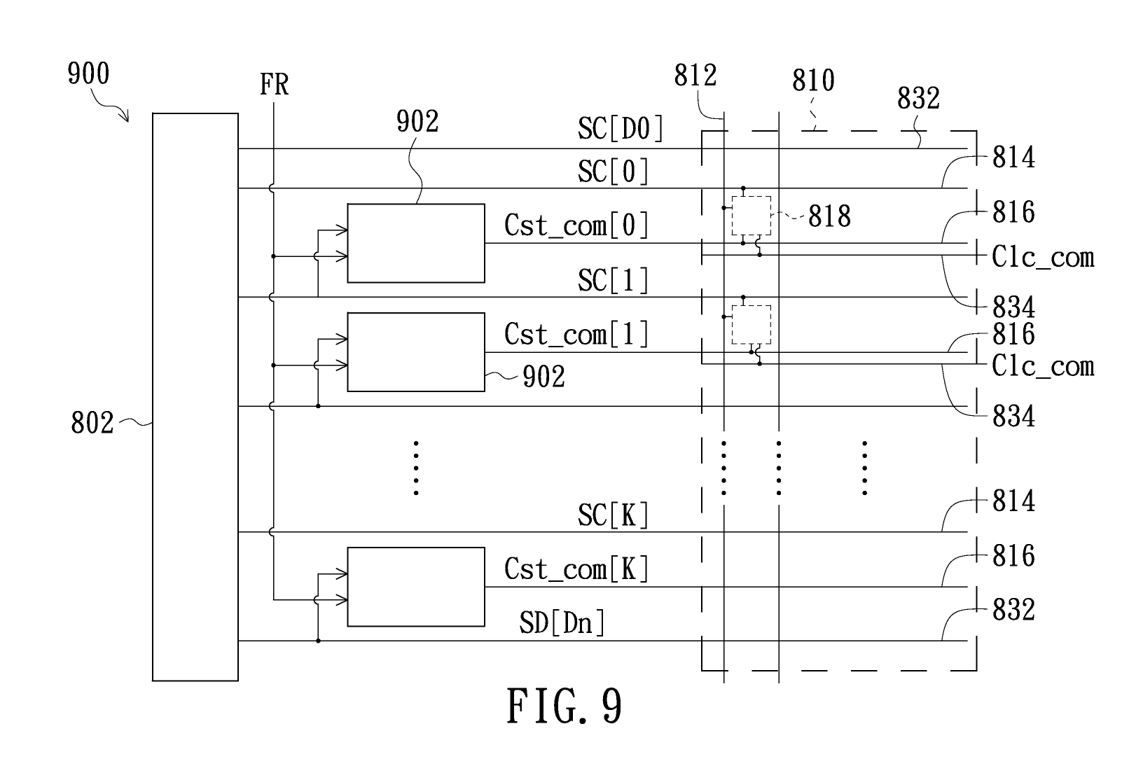

FIG. 9 is a schematic structure view of a display device in accordance with the sixth embodiment of the present disclosure. As shown, the display device 900 in this embodiment has a circuit structure similar to that of the display device 800. The main difference between the two is that the common voltage generators 902 in the display device 900 have the same circuit structure for generating the storage capacitor common voltage signals Cst_com; wherein the common voltage generator 902 may have a circuit structure same as that of the common voltage generators 202 or 204.

Likewise, in response to the above-described circuit structure, the signals associated with the display device 900 may be configured to have the timing sequences as schematically illustrated in FIG. 8B, except the input signal FR is required to be modulated to oscillate within a frame cycle and have an offset with a predetermined phase as shown in FIG. 4B and thereby configuring the storage capacitor common voltage signals Cst_com corresponding to twp adjacent pixel rows to have different polarities.

In summary, by selecting the output signal of the common voltage generator and configuring the frequency of the input signal FR to have one switched potential level within a frame, each common voltage signal Cst_com has opposite polarities in two consecutive frames and thereby reducing power consumption. In addition, because each inverter requires two transistors, the common voltage generator of the present disclosure may be implemented by six transistors only; consequentially, the display device of the present invention has lower hardware cost and has the slim border feature. Moreover, it is understood that the aforementioned disclosed embodiments are adapted to various types of pixel driving circuits in various display technology.

The aforementioned embodiments each are exemplified by configuring each scan signal SC to drive one respective common voltage generator and thereby generating one corresponding storage capacitor common voltage signal Cst_com. However, the present disclosure may generate the storage capacitor common voltage signals Cst_com[M] and Cst_com[M+1] by one respective scan signal SC[M]. The detail description will be described in the following embodiments.

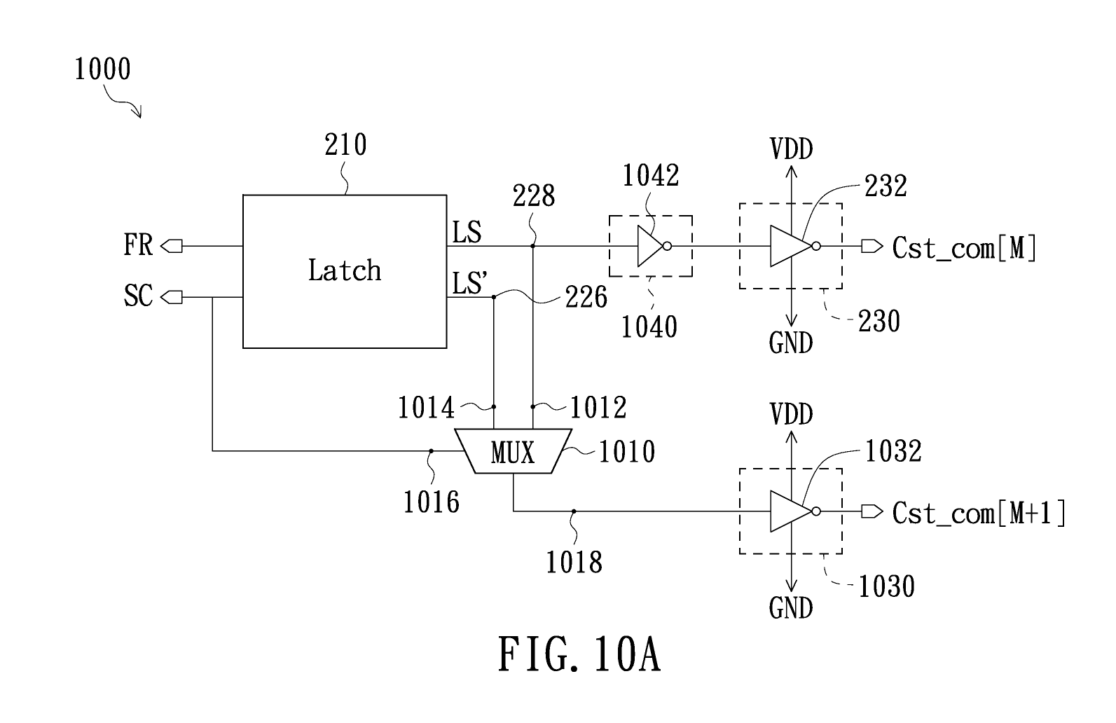

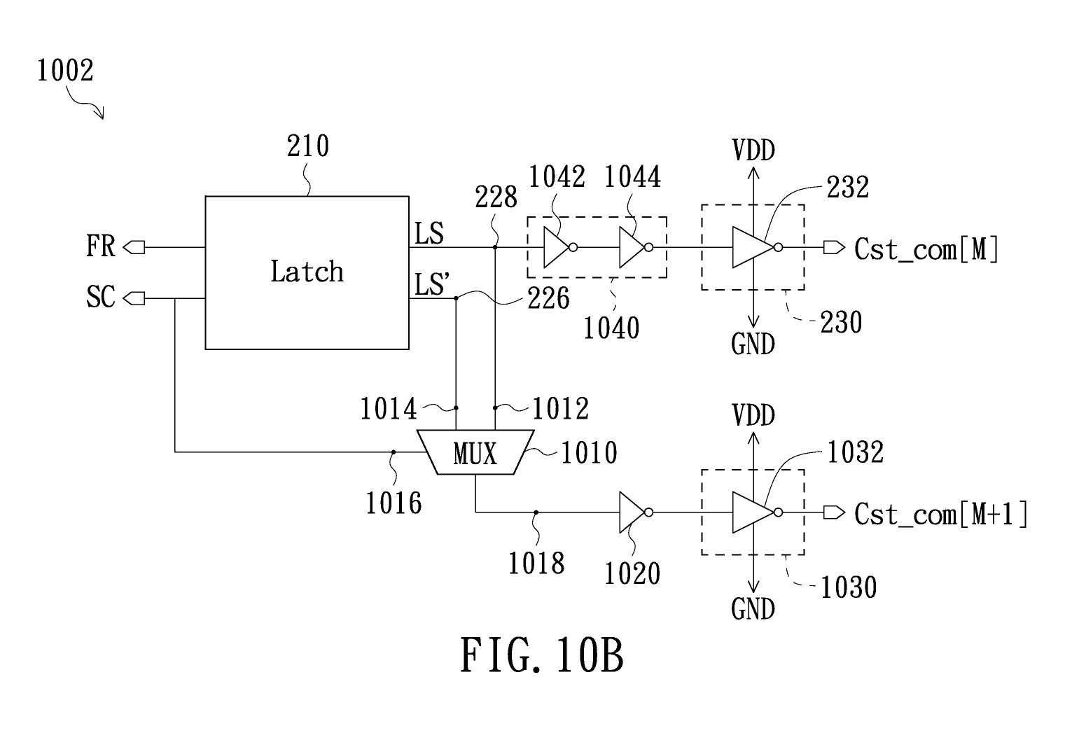

FIGS. 10A and 10B are schematic structure views of a common voltage generator in accordance with another embodiment of the present disclosure. Please refer to FIG. 10A first. As shown, the common voltage generator 1000 includes a latch 210, a buffer circuit 1040, voltage adjustment circuits 230 and 1030, and a multiplexer (MUX) 1010.

In this embodiment, the buffer circuit 1040 includes an inverter 1042 configured to have an input terminal thereof electrically coupled to the positive latch output terminal 228 of the latch 210 and an output terminal thereof electrically coupled to the input terminal of the inverter 232. In addition, the multiplexer 1010 has a first multiplex input terminal 1012 and a second multiplex input terminal 1014 electrically coupled to the positive latch output terminal 228 and the negative latch output terminal 226, respectively. In addition, the multiplexer 1010 further has a selection terminal 1016 for receiving the scan signal SC and a multiplex output terminal 1018. The multiplexer 1010 is configured to output, through the multiplex output terminal 1018 thereof, either the positive latch output signal LS or the negative latch output signal LS′ to the voltage adjustment circuit 1030 according to the potential level of the scan signal SC. In this embodiment, the voltage adjustment circuit 1030 includes an inverter 1032. Thus, by configuring the multiplexer 1010 to output an output signal with specific potential level, a corresponding storage capacitor common voltage signal Cst_com[M+1] is outputted from the voltage adjustment circuit 1030 (specifically, the output terminal of the inverter 1032).

Please refer to FIG. 10B. The common voltage generator 1002 disclosed in this embodiment has a circuit structure similar to that of the common voltage generator 1002. The main difference between the two is that the buffer circuit 1040 in the common voltage generator 1002 further includes an inverter 1044 disposed on the signal-transmission path from the inverter 1042 to the voltage adjustment circuit 230. In addition, the common voltage generator 1002 further includes an inverter 1020 disposed on the signal-transmission path from the multiplexer 1010 to the voltage adjustment circuit 1030. The operations of the common voltage generators 1000 and 1002 will be described in detail in the following paragraphs.

### Seventh Embodiment

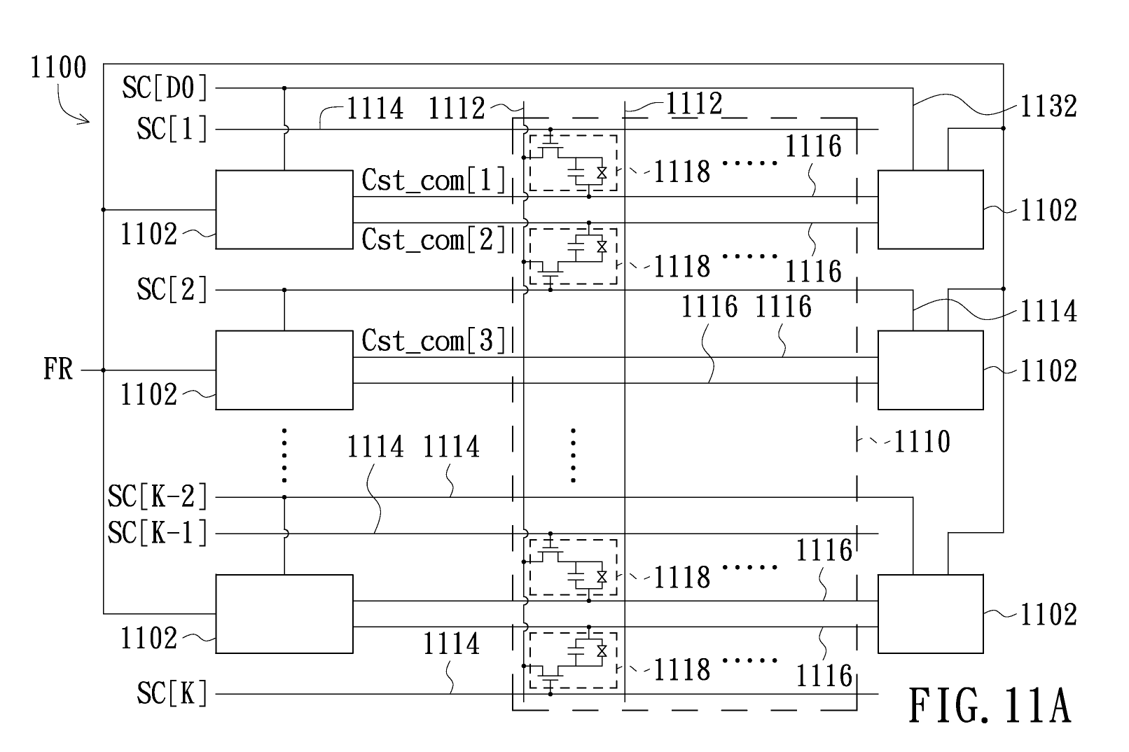

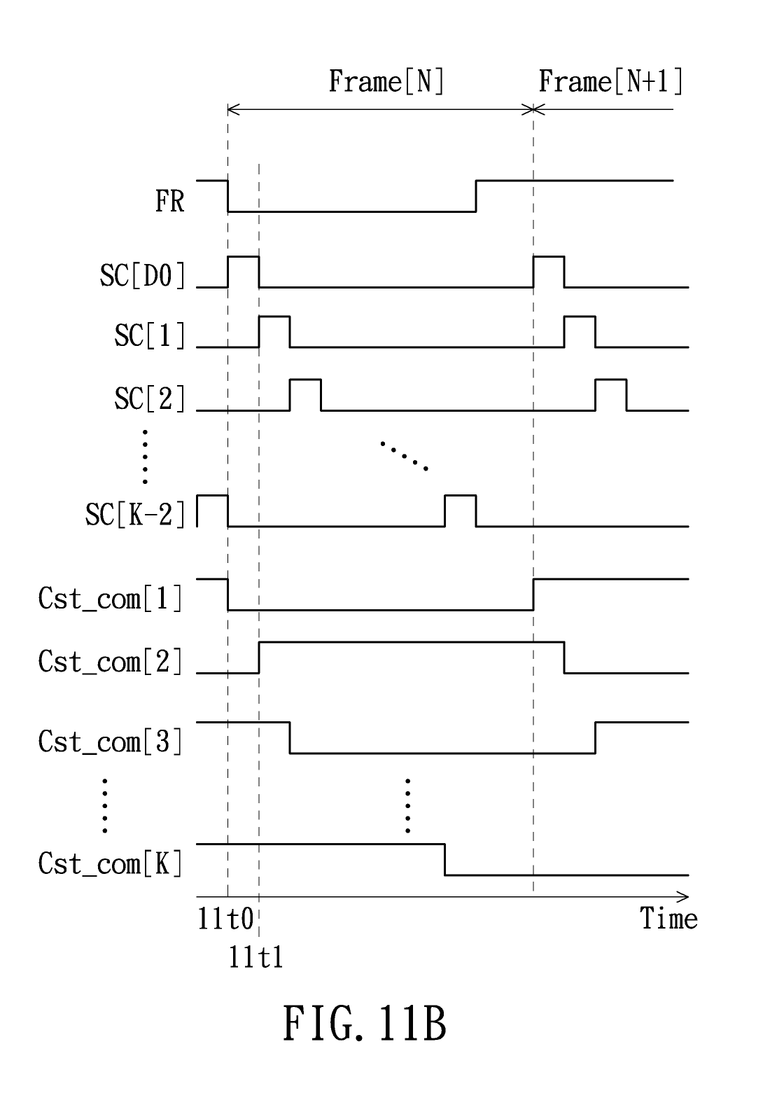

FIG. 11A is a schematic structure view of a display device in accordance with the seventh embodiment of the present disclosure. As shown, the display device 1100 in this embodiment includes a display area 1110 and a plurality of common voltage generators 1102. Specifically, the first portion of the common voltage generators 1102 is disposed on a first side of the display area 1110 and the second portion of the common voltage generators 1102 is disposed on a second side of the display area 1110; wherein the first and the second sides are opposite to each other. In this embodiment, each one of the common voltage generators 1102 is configured to receive the scan signal SC corresponding to the (M−1)ₜₕ pixel row and accordingly provide a storage capacitor common voltage signal Cst_com to the Mₜₕ pixel row and the (M+1)ₜₕ pixel row. In other words, each common voltage generator 1102 in this embodiment is configured to provide a storage capacitor common voltage signal Cst_com for the respective two adjacent pixel rows. In addition, each one of the common voltage lines 1116 is disposed with two common voltage generators 1102 at the two ends thereof, respectively. Thus, by simultaneously driving the pair of common voltage generators 1102, the voltage dropping effect resulted by the line resistance of the associated common voltage line 1116 is avoided.

As shown in FIG. 11A, the display area 1110 is disposed with a plurality of data lines 1112, a plurality of scan lines 1114, a plurality of common voltage lines 1116, and n dummy scan lines 1132 disposed before the first data line 1114. A pixel 1118 is arranged within an area defined by a respective data line 1112, a respective scan line 1114 and a respective common voltage line 1116.

In this embodiment, the common voltage generator 1102 may have a structure same as that of the common voltage generator 1000 in FIG. 10A. FIG. 11B is a schematic timing sequence view of the related signals in the display device 1100 in the seventh embodiment of the present disclosure. Please refer to FIGS. 10A, 11A and 11B. As shown, in this embodiment, the display device 1100 starts a new frame when the dummy scan signal SC[D0] is being enable. At time 11t0, when the scan signal (that is, the dummy scan signal SC[D0]) corresponding to the prior even-numbered pixel row is enable, the latch 210 in the common voltage generator 1102 (hereafter is also referred to the common voltage generator 1000) corresponding to the first pixel row is triggered and accordingly the positive latch output signal LS is outputted from the positive latch output terminal 228 thereof. The positive latch output signal LS is then further delivered to the first voltage adjustment circuit 232 through the inverter 1042. Then, the first voltage adjustment circuit 232 generates the storage capacitor common voltage signal Cst_com[1] having a potential level of ground GND by adjusting the potential level of the received positive latch output signal LS.

In addition, at time 11t0, the multiplexer 1010 in the common voltage generator 1000 is configured to selectively output, according to the potential level of the dummy scan signal SC[D0], the negative latch output signal LS′ to the second voltage adjustment circuit 1030 through the multiplex output terminal 1018 thereof. Then, the second voltage adjustment circuit 1030 generates the storage capacitor common voltage signal Cst_com[2] having a potential level of ground GND to the common voltage line 1116 corresponding to the second pixel row according to the potential level of the received negative latch output signal LS′.

At time 11t1, the dummy scan signal SC[D0] is disable. Because the potential levels of the positive latch output signal LS and the negative latch output signal LS′ of the common voltage generator 1000 corresponding to the first pixel row have no change (please refer the aforementioned related description for the in-detail information), the storage capacitor common voltage signal Cst_com[1] is maintained at the same potential level. However, because the dummy scan signal SC[D0] is converted to have a low potential level, the multiplexer 1010 in the common voltage generator 1000 corresponding to the first pixel row is configured to selectively output the positive latch output signal LS to the second voltage adjustment circuit 1030. Then, the second voltage adjustment circuit 1030 generates the storage capacitor common voltage signal Cst_com[2] having a potential level of power source VDD to the common voltage line 1116 corresponding to the second pixel row according to the potential level of the received positive latch output signal LS. The operations of the common voltage generators 1102 corresponding to the remaining rows of pixel 1118 can be obtained based on the same manner, and no redundant detail is to be given herein.

In summary, by configuring each common voltage generator to simultaneously provide a storage capacitor common voltage signal for the Mₜₕ and the (M+1)ₜₕ pixel rows, the display device in this embodiment has a slimmer border. In addition, by configuring two common voltage generators to simultaneously provide a storage capacitor common voltage signal for the same one common voltage line, the common voltage line has a smaller voltage drop and the display device in this embodiment has an image with higher uniformity.

### Eighth Embodiment

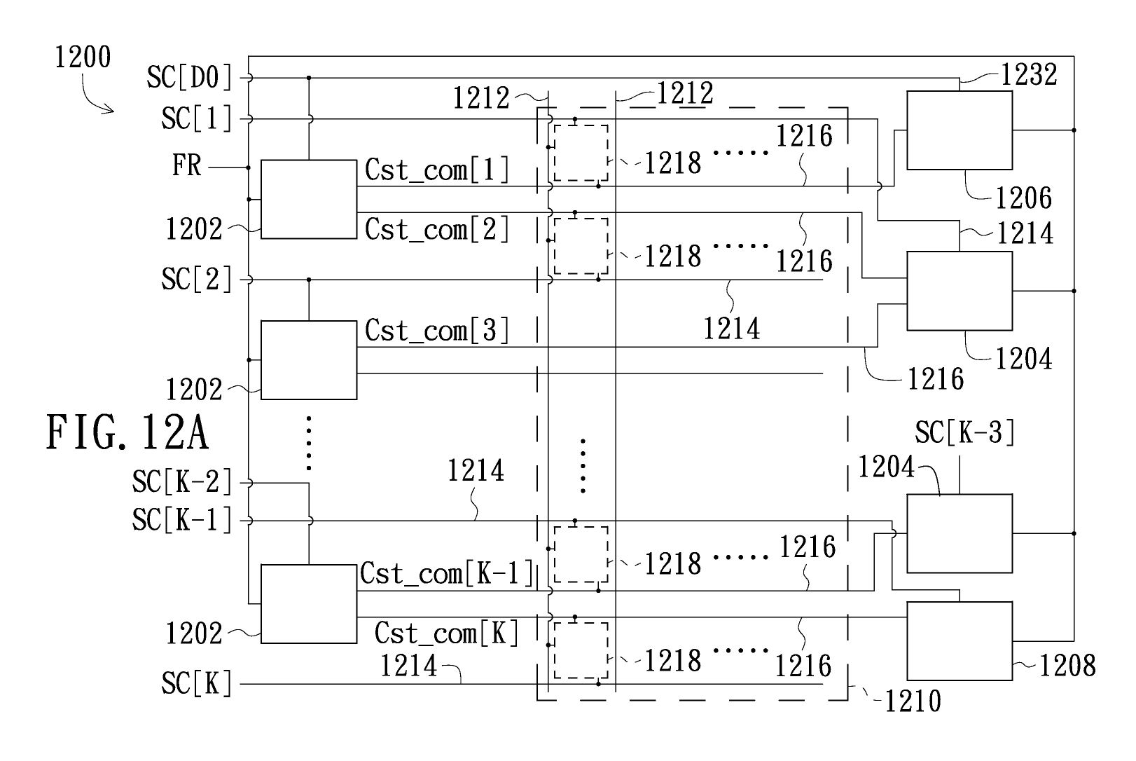

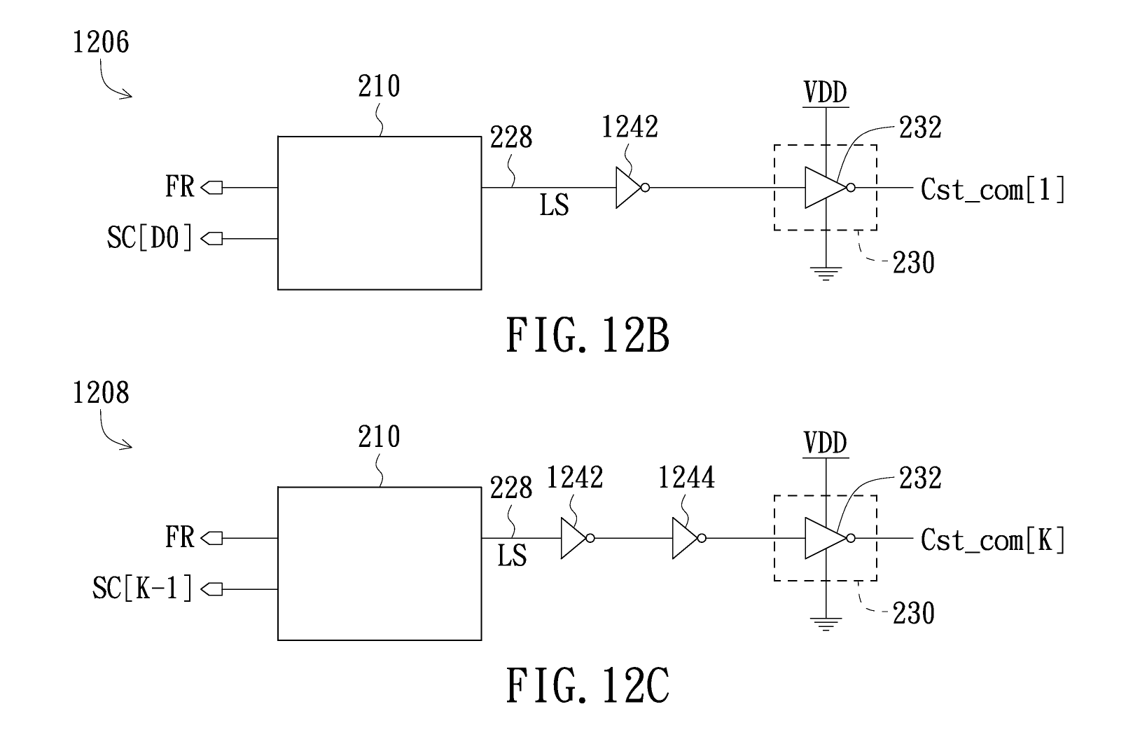

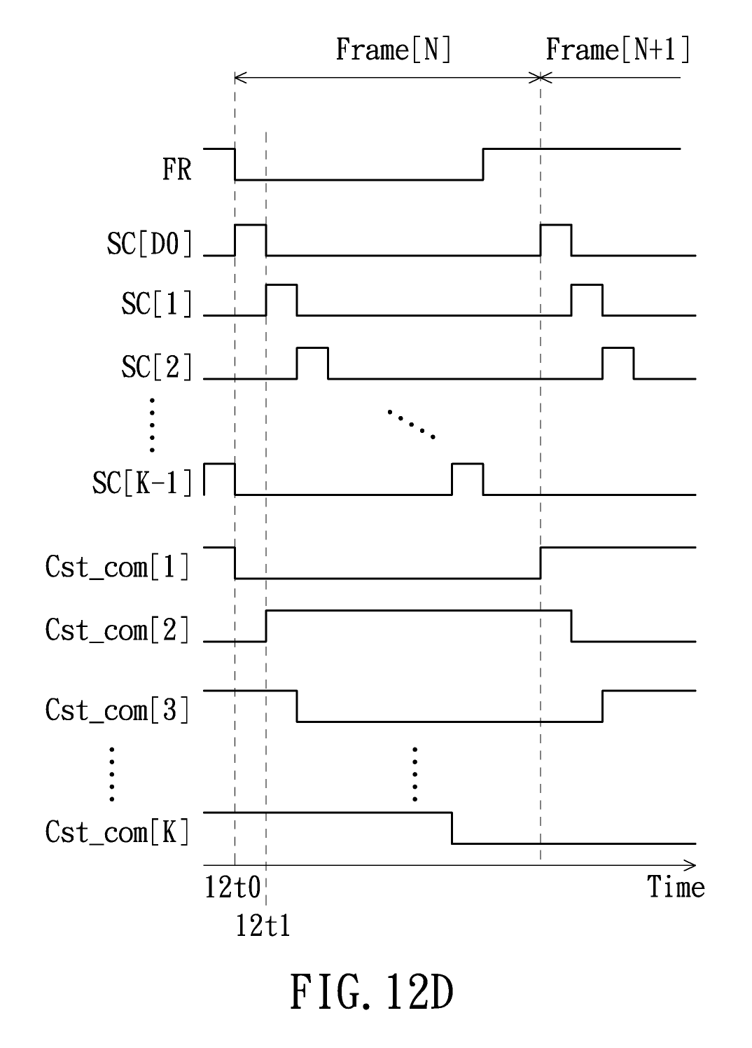

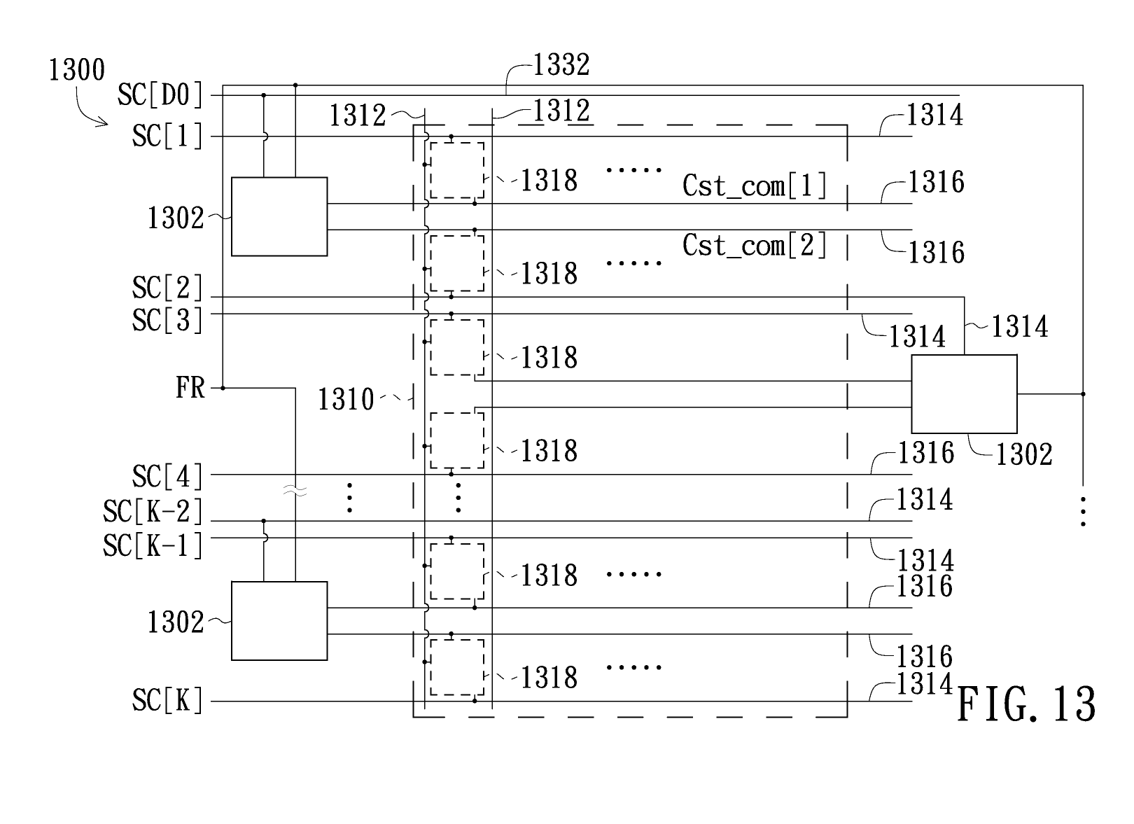

FIG. 12A is a schematic structure view of a display device in accordance with the eighth embodiment of the present disclosure. As shown, the display device 1200 in this embodiment includes a display area 1210, a plurality of first common voltage generators 1202 and a plurality of second common voltage generators 1204. Specifically, in order to configure the odd-numbered and even-numbered pixel rows to have the same load, the first common voltage generators 1202 are disposed on a first side of the display area 1210 and the second common voltage generators 1204 are disposed on a second side of the display area 1210. In this embodiment, it is to be noted that each one of the first common voltage generators 1202 and second common voltage generators 1204 is configured to provide the storage capacitor common voltage signal Cst_com for respective two adjacent pixel rows.

As shown in FIG. 12A, the display device 1200 in this embodiment further includes latch circuits 1206 and 1208 disposed on the second side of the display area 1210. Specifically, the latch circuit 1206 is disposed before the second common voltage generator 1204 corresponding to the first pixel row and configured to generate the storage capacitor common voltage signal Cst_com[1] corporately with the first common voltage generator 1202 corresponding to the first pixel row. The latch circuit 1208 is disposed after the second common voltage generator 1204 corresponding to the last pixel row and configured to generate the storage capacitor common voltage signal Cst_com[K] corporately with the first common voltage generator 1202 corresponding to the last pixel row.

As shown in FIG. 12A, the display area 1210 is disposed with a plurality of data lines 1212, a plurality of scan lines 1214 and a plurality of common voltage lines 1216. In addition, n dummy scan lines 1232 are disposed before the first data line 1214. A pixel 1218 is arranged within an area defined by a respective data line 1212, a respective scan line 1214 and a respective common voltage line 1216; wherein the pixel 1218 may have a circuit structure disclosed in FIG. 6, but the present invention is not limited thereto. In this embodiment, the first common voltage generator 1202 is configured to provide the storage capacitor common voltage signal Cst_com for the Mₜₕ and (M+1)ₜₕ pixel rows and the second common voltage generator 1204 is configured to provide the storage capacitor common voltage signal Cst_com for the (M+1)ₜₕ and (M+2)ₜₕ pixel rows; wherein M is a positive integer. In this embodiment, the first common voltage generator 1202 may have a circuit structure same as that of the common voltage generator 1000 in FIG. 10A and the second common voltage generator 1204 may have a circuit structure same as that of the common voltage generator 1002 in FIG. 10B; but the present invention is not limited thereto. Similar to the seventh embodiment, by configuring two adjacent common voltage generators to corporately provide the storage capacitor common voltage signal for the same one common voltage line 1216, the common voltage line 1216 in this embodiment has a smaller voltage drop. In addition, by electrically coupling the odd-numbered scan lines 1214 to the respective second common voltage generators 1204 and the even-numbered scan lines 1214 to the respective first common voltage generators 1202, each one of the scan lines 1214 in this embodiment has the same load.

FIG. 12B is a schematic structure view of the latch circuit 1206 in accordance with an embodiment of the present disclosure. As shown, the latch circuit 1206 includes a latch 210, an inverter 1242 and a voltage adjustment circuit 230. The latch 210 is configured to have the positive latch output terminal 228 thereof electrically coupled to the input terminal of the inverter 1242. The inverter 1242 is configured to have the output terminal thereof electrically coupled to the input terminal of the voltage adjustment circuit 230. Thus, by receiving the signal with a specific potential level outputted from the inverter 1242, the voltage adjustment circuit 230 accordingly generates and outputs the storage capacitor common voltage signal Cst_com[1].

FIG. 12C is a schematic structure view of the latch circuit 1208 in accordance with an embodiment of the present disclosure. As shown, the latch circuit 1208 has a structure similar to that of the latch circuit 1206. The main difference between the two is that the latch circuit 1208 further includes an inverter 1244 disposed on the signal-transmission path from the inverter 1242 to the voltage adjustment circuit 230. Thus, by receiving the signal with a specific potential level outputted from the inverter 1244, the voltage adjustment circuit 230 accordingly generates and outputs the storage capacitor common voltage signal Cst_com[K].

In another embodiment, the latch circuit 1206 may be replaced by the first common voltage generator 1202; and the latch circuit 1208 may be replaced by the second common voltage generator 1204.

FIG. 12D is a schematic timing sequence view of the signals associated with the display device 1200 in the eighth embodiment of the present disclosure. Please refer to FIGS. 10A, 10B and 12A˜12D. As shown, at time 12t0, the display device 1200 starts a new frame when the dummy scan signal SC[D0] is being enable. Meanwhile at time 12t0, the latch 210 in the latch circuit 1206 is triggered, and accordingly the positive latch output signal LS is outputted from the positive latch output terminal 228 thereof. In addition, at time 12t0, the latch 210 in the first common voltage generator 1202 (hereafter is also referred to the common voltage generator 1000) corresponding to the second pixel row is also triggered; and accordingly the positive latch output signal LS is outputted from the positive latch output terminal 228 thereof.

In the latch circuit 1206, the positive latch output signal LS is further delivered to the inverter 1242; and, by receiving the signal with a specific potential level outputted from the inverter 1242, the voltage adjustment circuit 230 accordingly generates and outputs the storage capacitor common voltage signal Cst_com[1] having a potential level of ground GND to the first common voltage line 1216. Meanwhile, the voltage adjustment circuit 230, in the corresponding common voltage generator 1000 disposed on a side of the second row of pixel 1218, also generates and outputs the storage capacitor common voltage signal Cst_com[1] having a potential level of ground GND to the first common voltage line 1216.

In addition, at time 12t0, the multiplexer 1010 corresponding to the second pixel row in the common voltage generator 1000 is configured to selectively output, according to the potential level of the dummy scan signal SC[D0], the negative latch output signal LS′ to the voltage adjustment circuit 1030 through the multiplex output terminal 1018 thereof. Then, voltage adjustment circuit 1030 generates the storage capacitor common voltage signal Cst_com[2] having a potential level of ground GND to the common voltage line 1216 corresponding to the second pixel row according to the potential level of the received negative latch output signal LS′.

At time 12t1, the dummy scan signal SC[D0] is disable. As mentioned above, the storage capacitor common voltage signal Cst_com[1] is maintained at the same potential level. However, because the dummy scan signal SC[D0] is converted to have a low potential level, the multiplexer 1010 in the common voltage generator 1000 corresponding to the second pixel row is configured to selectively output the positive latch output signal LS to the voltage adjustment circuit 1030 through the multiplex output terminal 1018 thereof. Then, the voltage adjustment circuit 1030 generates the storage capacitor common voltage signal Cst_com[2] having a potential level of power source VDD to the common voltage line 1216 corresponding to the second pixel row according to the potential level of the received positive latch output signal LS.

In addition, at time 12t1, the latch 210 in the common voltage generator 1204 (hereafter is also referred to the common voltage generator 1002) corresponding to the third pixel row is triggered by the scan signal SC[1]. Accordingly, the positive latch output signal LS is outputted from the positive latch output terminal 228 of the latch 210 and delivered to the voltage adjustment circuit 230 through the buffer circuit 1040. Then, the voltage adjustment circuit 230 generates the storage capacitor common voltage signal Cst_com[2] having a potential level of voltage source VDD to the common voltage line 1216 corresponding to the second pixel row according to the potential level of the signal outputted from the buffer circuit 1040.

In addition, at time 12t1, the multiplexer 1010 corresponding to the third pixel row in the common voltage generator 1002 is configured to selectively output, according to the potential level of the scan signal SC[1], the negative latch output signal LS′ derived from the latch 210 to the inverter 1020. Then, the voltage adjustment circuit 1030 generates the storage capacitor common voltage signal Cst_com[3] having a potential level of power source VDD to the common voltage line 1216 corresponding to the third pixel row according to the potential level of the signal outputted from the inverter 1020 until the scan signal SC[1] is converted back to have a low potential level. The operations of the remaining common voltage generators 1202, 1204 and the latch circuits 1206, 1208 can be obtained based on the same manner, and no redundant detail is to be given herein.

### Ninth Embodiment

FIG. 13 is a schematic structure view of a display device in accordance with the ninth embodiment of the present disclosure. As shown, the display device 1300 in this embodiment includes a plurality of common voltage generators 1302 and a display area 1310. Each one of the common voltage generators 1302 is configured to provide a storage capacitor common voltage signal Cst_com to the respective two adjacent pixel rows. Specifically, in order to reduce the layout area, the common voltage lines 316 can be driven in one side manner in this embodiment. For example, the common voltage generator 1302, configured to provide the storage capacitor common voltage signal Cst_com for the Mₜₕ and (M+1)ₜₕ pixel rows, may be disposed on a first side of the display area 1310; and the common voltage generator 1302, configured to provide the storage capacitor common voltage signal Cst_com for the (M+2)ₜₕ and (M+3)ₜₕ pixel rows, may be disposed on a second side of the display area 1310. In other words, any two adjacent common voltage generators 1302 are disposed on two different sides of the display area 1310 in this embodiment.

As shown in FIG. 13, the display area 1310 is disposed with a plurality of data lines 1312 and a plurality of scan lines 1314. Furthermore, a pixel 1318 is arranged within an area defined by a respective data line 1312, a respective scan line 1314 and a respective common voltage line 1316; wherein the pixel 1318 in this embodiment may have a circuit structure disclosed in FIG. 6, but the present invention is not limited thereto. In this embodiment, it is to be noted that the display device 1300 is further disposed with n dummy scan lines 1322 before the first scan line 1313; wherein n is 1 or 2, but the present invention is not limited thereto. In this embodiment, each one of common voltage generators 1302 is configured to receive the scan signal SC transmitted from the respective last even-numbered scan line 1314 as a trigger signal thereof.

In this embodiment, each one of common voltage generators 1302 has an operation manner same as that in the common voltage generator 1204 disclosed in the aforementioned embodiment; and no redundant detail is to be given herein. Thus, by arranging each two adjacent common voltage generators 1302 on two different sides of the display area 1310, the display area 1310 in this embodiment has a flexible layout arrangement and consequentially the display device 1300 has a slimmer border.

In summary, by configured each common voltage generator to provide the storage capacitor common voltage signal for two adjacent common voltage lines, the display device in the aforementioned embodiments may need less number of transistors therein, and accordingly has a slimmer border and a more compact size.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A voltage generator, comprising:
a latch comprising a latch input terminal, a trigger terminal, a positive latch output terminal and a negative latch output terminal, the latch being configured to have the latch input terminal thereof for receiving an input signal, the trigger terminal thereof for receiving a trigger signal, the positive latch output terminal thereof for outputting a first latch output signal having a phase same as that of the input signal, and the negative latch output terminal thereof for outputting a second latch output signal having a phase opposite to that of the input signal; and
a first voltage adjustment circuit electrically coupled to the latch and configured to output a first common voltage signal.

2. The voltage generator according to claim 1, wherein the latch comprises:
a first switch unit having a first terminal electrically coupled to the latch input terminal, a control terminal electrically coupled to the trigger terminal, and a second terminal, the first switch unit being configured to have the first and second terminals thereof electrically conductive to each other while the trigger signal has a first potential level;
a second switch unit having a first terminal electrically coupled to the second terminal of the first switch unit, a control terminal electrically coupled to the trigger terminal, and a second terminal electrically coupled to the positive latch output terminal, the second switch unit being configured to have the first and second terminals thereof electrically conductive to each other while the trigger signal has a second potential level, wherein the second potential level has a polarity different to that of the first potential level;
a first inverter having an input terminal electrically coupled to the second terminal of the first switch unit and an output terminal electrically coupled to the negative latch output terminal; and
a second inverter having an input terminal electrically coupled to the output terminal of the first inverter and an output terminal electrically coupled to the positive latch output terminal.

3. The voltage generator according to claim 2, wherein the first voltage adjustment circuit is electrically coupled to the positive latch output terminal and from which to receive the first latch output signal.

4. The voltage generator according to claim 2, wherein the first voltage adjustment circuit is electrically coupled to the negative latch output terminal and from which to receive the second latch output signal.

5. The voltage generator according to claim 1, further comprising:
a multiplexer comprising a first input terminal, a second input terminal, a selection terminal and an output terminal, the first and second input terminals being electrically coupled to the positive and negative latch output terminals, respectively, the selection terminal being electrically coupled to the trigger signal, the multiplexer being configured to output either the first latch output signal or the second latch output signal according to the trigger signal; and
a second voltage adjustment circuit electrically coupled to the output terminal of the multiplexer and configured to output a second common voltage signal.

6. The voltage generator according to claim 5, further comprising:
a buffer circuit comprising a buffer input terminal and a buffer output terminal electrically coupled to the positive latch output terminal and the input terminal of the first voltage adjustment circuit, respectively.

7. A display device, comprising:
a display area comprising a plurality of pixel rows, a plurality of scan lines and a plurality of common voltage lines, each one of the scan lines and each one of the common voltage lines being corresponding to one of the pixel rows, each one of the pixel rows being constituted by a plurality of pixel units; and
a plurality of common voltage generators electrically coupled to the common voltage lines, respectively, each one of the common voltage generators being corresponding to at least one of the pixel rows and comprising:
a latch comprising a latch input terminal, a trigger terminal, a positive latch output terminal and a negative latch output terminal, the latch being configured to have the latch input terminal thereof for receiving an input signal, the trigger terminal thereof for receiving a trigger signal, the positive latch output terminal thereof for outputting a first latch output signal having a phase same as that of the input signal, and the negative latch output terminal thereof for outputting a second latch output signal having a phase opposite to that of the input signal; and
a voltage adjustment circuit electrically coupled to the latch and configured to output a first common voltage signal to a corresponding common voltage line.

8. The display device according to claim 7, wherein the voltage adjustment circuit, in each one of the common voltage generators electrically coupled to an respective even-numbered pixel row, is electrically coupled to the positive latch output terminal and from which to receive the first latch output signal, and the voltage adjustment circuit, in each one of the common voltage generators electrically coupled to an respective odd-numbered pixel row, is electrically coupled to the negative latch output terminal and from which to receive the second latch output signal; or, wherein the voltage adjustment circuit, in each one of the common voltage generators electrically coupled to an respective odd-numbered pixel row, is electrically coupled to the positive latch output terminal and from which to receive the first latch output signal, and the voltage adjustment circuit, in each one of the common voltage generators electrically coupled to an respective even-numbered pixel row, is electrically coupled to the negative latch output terminal and from which to receive the second latch output signal.

9. The display device according to claim 7, wherein the voltage adjustment circuit in each one of the common voltage generators is electrically coupled to the positive latch output terminal and from which to receive the first latch output signal and accordingly generates the common voltage signal.

10. The display device according to claim 7, wherein the voltage adjustment circuit in each one of the common voltage generators is electrically coupled to the negative latch output terminal and from which to receive the second latch output signal and accordingly generates the common voltage signal.

11. The display device according to claim 7, wherein the voltage adjustment circuit corresponding to the Mₜₕ pixel row is electrically coupled to the Mₜₕ scan line and from which to receive the scan signal corresponding to the Mₜₕ pixel row as the trigger signal, wherein M is an integer greater than or equal to 0.

12. The display device according to claim 7, wherein the voltage adjustment circuit corresponding to the Mₜₕ pixel row is electrically coupled to the (M−n)ₜₕ scan line and from which to receive the scan signal corresponding to the (M−n)ₜₕ pixel row as the trigger signal, wherein M is an integer greater than or equal to 0 and n is a natural number.

13. The display device according to claim 12, further comprising at least (n+1) dummy scan lines disposed before the scan lines.

14. The display device according to claim 13, further comprising a plurality of data lines, and each one of the pixel units comprising:
a thin film transistor comprising a first terminal electrically coupled to one of the data lines and a gate terminal electrically coupled to one of the scan lines;
a liquid crystal capacitor comprising a first terminal electrically coupled to a second terminal of the thin film transistor and a second terminal electrically coupled to one of the first common voltage lines; and
a storage capacitor comprising a first terminal electrically coupled to the first terminal of the liquid crystal capacitor and a second terminal electrically coupled to the second terminal of the liquid crystal capacitor.

15. The display device according to claim 7, wherein the voltage adjustment circuit corresponding to the Mₜₕ pixel row is electrically coupled to the (M+n)ₜₕ scan line and from which to receive the scan signal corresponding to the (M+n)ₜₕ pixel row as the trigger signal, wherein M is an integer greater than or equal to 0 and n is a natural number.

16. The display device according to claim 15, further comprising at least n dummy scan lines disposed after the scan lines.

17. The display device according to claim 7, wherein the latch comprises:
a first switch unit comprising a first terminal electrically coupled to the latch input terminal, a control terminal electrically coupled to the trigger terminal, and a second terminal, wherein the first switch unit is configured to have the first and second terminals thereof electrically conductive to each other while the trigger signal has a first potential level;
a second switch unit comprising a first terminal electrically coupled to the second terminal of the first switch unit, a control terminal electrically coupled to the trigger terminal and a second terminal electrically coupled to the positive latch output terminal, wherein the second switch unit is configured to have the first and second terminals thereof electrically conductive to each other while the trigger signal has a second potential level, wherein the second potential level has a polarity different to that of the first potential level;
a first inverter comprising an input terminal electrically coupled to the second terminal of the first switch unit and an output terminal electrically coupled to the negative latch output terminal; and
a second inverter comprising an input terminal electrically coupled to the output terminal of the first inverter and an output terminal electrically coupled to the positive latch output terminal.

18. The display device according to claim 7, further comprising a plurality of data lines and at least a second common voltage line, the one or more second common voltage lines each being corresponding to one of the pixel rows, and each one of the pixel units comprising:
a thin film transistor comprising a first terminal electrically coupled to one of the data lines and a gate terminal electrically coupled to one of the scan lines;
a liquid crystal capacitor comprising a first terminal electrically coupled to a second terminal of the thin film transistor and a second terminal electrically coupled to one of the second common voltage lines, wherein the second common voltage line is configured to transmit a liquid crystal common voltage signal; and
a storage capacitor comprising a first terminal electrically coupled to the second terminal of the thin film transistor and a second terminal electrically coupled to one of the first common voltage lines and from which to receive the common voltage signal.

19. The display device according to claim 7, wherein the input signal is configured to oscillate between a first potential level and a second potential level in a frame, the input signal is configured to have a rising edge and a falling edge thereof with a delayed phase relative to the rising edges of the scan signals, thereby configuring the latch to selectively generate the first latch output signal or the second latch output signal according to the input signal and the trigger signal.

20. The display device according to claim 7, wherein the input signal is configured to be maintained at a specific potential level in a frame and thereby configuring the latch to selectively generate the first latch output signal or the second latch output signal according to the input signal and the trigger signal.

21. The display device according to claim 13, wherein the input signal is configured to be maintained at a specific potential level in a frame, and the frame comprises an enable time of the dummy scan lines.

22. The display device according to claim 16, wherein the input signal is configured to be maintained at a specific potential level in a frame, and the frame comprises an enable time of the dummy scan lines.

23. A display device, comprising:
a display area comprising a plurality of pixel rows, a plurality of scan lines and a plurality of common voltage lines, each one of the scan lines and each one of the common voltage lines being corresponding to one of the pixel rows;
a plurality of first common voltage generators disposed on a first side of the display area and each being configured to provide a common voltage signal to the respective two adjacent pixel rows, and
a plurality of second common voltage generators disposed on a second side of the display area and each being configured to provide the common voltage signal to the respective two adjacent pixel rows, wherein each one of the first and second common voltage generators comprises:
a latch comprising a latch input terminal for receiving an input signal, a trigger terminal for receiving a scan signal, a positive latch output terminal for outputting a positive latch output signal having a phase same as that of the input signal, and a negative latch output terminal for outputting a negative latch output signal having a phase opposite to that of the input signal;
a buffer circuit comprising an input terminal electrically coupled to the positive latch output terminal of the latch;
a first voltage adjustment circuit configured to output a common voltage signal corresponding to a first of two adjacent pixel rows according to the potential level at an output terminal of the buffer circuit;
a multiplexer comprising a first multiplex input terminal, a second multiplex input terminal, a selection terminal and an multiplex output terminal, the first and second multiplex input terminals being electrically coupled to the positive and negative latch output terminals of the latch, respectively, the selection terminal being electrically coupled to the scan signal received by the latch, the multiplexer being configured to output either the first latch output signal or the second latch output signal via the multiplex output terminal thereof according to the scan signal; and
a second voltage adjustment circuit electrically coupled to the multiplexer and configured to output a common voltage signal corresponding to a second of the two adjacent rows of pixel according to the potential level at the multiplex output terminal.

24. The display device according to claim 23, wherein each one of the second common voltage generators further comprises:
an inverter electrically coupled between the multiplexer and the second voltage adjustment circuit.

25. The display device according to claim 23, wherein the latch comprises:
a first switch unit comprising a first terminal electrically coupled to the latch input terminal, a control terminal electrically coupled to the trigger terminal, and a second terminal, wherein the first switch unit is configured to have the first and second terminals thereof electrically conductive to each other while the scan signal has a first potential level;
a second switch unit comprising a first terminal electrically coupled to the second terminal of the first switch unit, a control terminal electrically coupled to the trigger terminal and a second terminal electrically coupled to the positive latch output terminal, wherein the second switch unit is configured to have the first and second terminals thereof electrically conductive to each other while the scan signal has a second potential level, the second potential level has a polarity different to that of the first potential level;
a first inverter comprising an input terminal electrically coupled to the second terminal of the first switch unit and an output terminal electrically coupled to the negative latch output terminal; and
a second inverter comprising an input terminal electrically coupled to the output terminal of the first inverter and an output terminal electrically coupled to the positive latch output terminal.

26. The display device according to claim 23, wherein each one of the first common voltage generators is corresponding to one of the second common voltage generators, and the corresponding first and second common voltage generators are electrically coupled to two opposite sides of the respective two adjacent pixel rows, respectively.

27. The display device according to claim 23, wherein each one of the first common voltage generators is configured to generate the common voltage signal corresponding to the (4M−3)ₜₕ and the (4M−2)ₜₕ pixel rows, each one of the second common voltage generators is configured to generate the common voltage signal corresponding to the (4M−1)ₜₕ and the 4Mₜₕ pixel rows, M is an integer greater than 0.

28. The display device according to claim 24, wherein each one of the first common voltage generators is configured to generate the common voltage signal corresponding to the (2M−1)ₜₕ and the 2Mₜₕ pixel rows, each one of the second common voltage generators is configured to generate the common voltage signal corresponding to the 2Mₜₕ and the (2M+1)ₜₕ pixel rows, M is an integer greater than 0.

29. The display device according to claim 28, further comprising:
a first latch circuit electrically coupled to the first pixel row and configured to output a common voltage signal to the common voltage line corresponding to the first pixel row; and
a second latch circuit electrically coupled to the last pixel row and configured to output the common voltage signal to the common voltage line corresponding to the last pixel row.

30. The display device according to claim 29,
wherein the first latch circuit comprises:
a first latch comprising a latch input terminal for receiving an input signal and a trigger terminal for receiving the scan signal corresponding to a dummy scan line, wherein the first latch is configured to output a positive latch output signal having a phase same as that of the input signal according to the received trigger signal, the dummy scan line is disposed before the scan lines;
a third inverter configured to receive the positive latch output signal outputted from the first latch; and
a third voltage adjustment circuit configured to output the common voltage signal corresponding to the first row of pixel according to the potential level at an output terminal of the third inverter;
wherein the second latch circuit comprises:
a second latch comprising a latch input terminal for receiving an input signal and a trigger terminal for receiving the scan signal corresponding to the penultimate dummy scan line, wherein the first latch is configured to output a positive latch output signal having a phase same as that of the input signal according to the received scan signal;
a fourth inverter configured to receive the positive latch output signal outputted from the second latch;
a fifth inverter electrically coupled to an output terminal of the fourth inverter; and
a fourth voltage adjustment circuit configured to output the common voltage signal corresponding to the last row of pixel according to the potential level at an output terminal of the fifth inverter.
